(19) United States
(12) Patent Application Publication
(10) Pub. No.: US 2026/0162604 A1
(43) Pub. Date: Jun. 11, 2026

(54) Display Substrate and Driving Method Thereof, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Haigang QING, Beijing (CN); Gukhwan SONG, Beijing (CN); Benlian WANG, Beijing (CN); Hai ZHENG, Beijing (CN); Ming HU, Beijing (CN); Haijun QIU, Beijing (CN)

(21) Appl. No.: 18/842,406

(22) PCT Filed: Sep. 25, 2023
(86) PCT No.: PCT/CN2023/120988

§ 371 Date: Aug. 29, 2024

(51) Int. Cl. G09G 3/3233

(52) U.S. Cl. CPC G09G 3/3233; G09G 2300/0819; G09G 2310/08; G09G 2320/0233; G09G 2320/0247; G09G 2330/021

(57) ABSTRACT

A display substrate, a driving method thereof, and a display apparatus. The display substrate includes multiple circuit units. A circuit unit at least includes a pixel drive circuit, and at least one control signal line (24, 25) configured to provide a control signal to the pixel drive circuit. In at least one circuit unit, the pixel drive circuit at least includes a drive transistor (T3), a first control transistor (T5, T8) and a second control transistor (T6, T7), the first control transistor (T5, T8) and second control transistor (T6, T7) are connected to the drive transistor (T3), respectively; in at least one pixel drive circuit of at least one unit row, the first control transistor (T5, T8) is connected to a control signal line (24, 25) in a previous unit row, the second control transistor (T6, T7) is connected to control signal line (24, 25) in the current unit row.

### CROSS-REFERENCE TO RELATED APPLICATION

The present application is a U.S. National Phase Entry of International Application No. PCT/CN2023/120988 having an international filing date of Sep. 25, 2023, the content of which is hereby incorporated by reference.

### TECHNICAL FIELD

The present disclosure relates to, but is not limited to, the field of display technologies, and particularly to a display substrate and a driving method for the display substrate, and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With continuous development of display technologies, a display in which an OLED or a QLED is used as a light emitting device and a Thin Film Transistor (TFT) is used for signal control has become a mainstream product in the field of display at present.

### SUMMARY

The following is a summary of subject matters described herein in detail. This summary is not intended to limit the protection scope of claims.

In one aspect, the present disclosure provides a display substrate, including a plurality of circuit units constituting a plurality of unit rows and a plurality of unit columns, wherein at least one circuit unit at least includes a pixel drive circuit and at least one control signal line configured to provide a control signal to the pixel drive circuit; in at least one circuit unit, the pixel drive circuit at least includes a drive transistor, a first control transistor and a second control transistor, the first control transistor and the second control transistor are connected to the drive transistor, respectively; and in at least one pixel drive circuit of at least one unit row, the first control transistor is connected to a control signal line in a previous unit row, and the second control transistor is connected to a control signal line in the current unit row.

In an exemplary implementation, the control signal line includes a light emitting signal line, the first control transistor includes a first light emitting control transistor, the second control transistor includes a second light emitting control transistor, a first electrode of the first light emitting control transistor is connected to a first power supply line, a second electrode of the first light emitting control transistor is connected to a first electrode of the drive transistor, and a first electrode of the second light emitting control transistor is connected to a second electrode of the drive transistor; in at least one pixel drive circuit of at least one unit row, a gate electrode of the first control transistor is connected to a light emitting signal line in a previous unit row, and a gate electrode of the second control transistor is connected to a light emitting signal line in the current unit row.

In an exemplary implementation, in at least one pixel drive circuit, the first light emitting control transistor and the second light emitting control transistor connected to a same drive transistor are respectively arranged on two sides of the drive transistor in a unit column direction.

In an exemplary implementation, the first light emitting control transistor at least includes a first light emitting control active layer, and the second light emitting control transistor at least includes a second light emitting control active layer; and in at least one pixel drive circuit of at least one unit row, the first light emitting control active layer is arranged in a circuit unit of a previous unit row, and the second light emitting control active layer is arranged in a circuit unit of the current unit row.

In an exemplary implementation, in at least one pixel drive circuit of at least one unit row, the first light emitting control active layer is arranged on a side of a second light emitting control active layer of a pixel drive circuit in a previous unit row in a unit row direction.

In an exemplary implementation, the pixel drive circuit further includes a storage capacitor and a power supply connection electrode, the storage capacitor includes a first plate and a second plate, an orthographic projection of the first plate on a plane of the display substrate overlaps at least partially with an orthographic projection of the second plate on the plane of the display substrate; in at least one pixel drive circuit of at least one unit row, a first terminal of the power supply connection electrode is connected to a first region of the first light emitting control active layer of the pixel drive circuit in a next unit row, and a second terminal of the power supply connection electrode is connected to the second plate of the pixel drive circuit in the current unit row.

In an exemplary implementation, the control signal line includes a scan signal line, the first control transistor includes a third initialization transistor, the second control transistor includes a second initialization transistor, a first electrode of the second initialization transistor is connected to a second initial signal line, a second electrode of the second initialization transistor is connected to a second electrode of the drive transistor through a second light emitting control transistor, a first electrode of the third initialization transistor is connected to a third initial signal line, and a second electrode of the third initialization transistor is connected to a first electrode of the drive transistor; and in at least one pixel drive circuit of at least one unit row, a gate electrode of the third initialization transistor is connected to a scan signal line in a previous unit row, and a gate electrode of the second initialization transistor is connected to a scan signal line in the current unit row.

In an exemplary implementation, in at least one pixel drive circuit, the second initialization transistor and the third initialization transistor connected to a same drive transistor are respectively arranged on two sides of the drive transistor in a unit column direction.

In an exemplary implementation, the second initialization transistor at least includes a second initialization active layer, and the third initialization transistor at least includes a third initialization active layer; and in at least one pixel drive circuit of at least one unit row, the third initialization active layer is arranged in a circuit unit of a previous unit row, and the second initialization active layer is arranged in a circuit unit of the current unit row.

In an exemplary implementation, in at least one pixel drive circuit of at least one unit row, the third initialization active layer is arranged on a side of a second initialization active layer of a pixel drive circuit in a previous unit row in a unit row direction.

In an exemplary implementation, in at least one pixel drive circuit of at least one unit row, a first region of the second initialization active layer is connected to the second initial signal line in the current unit row, and a first region of a third initialization active layer is connected to the third initial signal line in a previous unit row.

In an exemplary implementation, the pixel drive circuit further includes a first initialization transistor, a compensation transistor and an isolation transistor, a first electrode of the first initialization transistor is connected to a first initial signal line, a second electrode of the first initialization transistor and a first electrode of the compensation transistor are connected to a first electrode of the isolation transistor, a second electrode of the isolation transistor is connected to a gate electrode of the drive transistor, and a second electrode of the compensation transistor is connected to a second electrode of the drive transistor.

In an exemplary implementation, the pixel drive circuit further includes a data writing transistor, a first electrode of the data writing transistor is connected to a data signal line, and a second electrode of the data writing transistor is connected to the first electrode of the drive transistor; and a channel region of the isolation transistor is located between a channel region of the compensation transistor and a channel region of the data writing transistor, and a channel width-length ratio of the isolation transistor is greater than a channel width-length ratio of the data writing transistor.

In an exemplary implementation, the first control transistor includes a first light emitting control transistor and a third initialization transistor, a first electrode of the first light emitting control transistor is connected to a first power supply line, a first electrode of the third initialization transistor is connected to a third initial signal line, and a second electrode of the first light emitting control transistor and a second electrode of the third initialization transistor are connected to the first electrode of the drive transistor; and the pixel drive circuit further includes a second node electrode connected to the first electrode of the drive transistor, the second electrode of the first light emitting control transistor and the second electrode of the third initialization transistor, respectively, and an orthographic projection of the second node electrode on the plane of the display substrate overlaps at least partially with an orthographic projection of the first initial signal line on the plane of the display substrate.

In an exemplary implementation, the pixel drive circuit further includes a first initialization transistor and a compensation transistor, a first electrode of the first initialization transistor is connected to a first initial signal line, a second electrode of the first initialization transistor and a first electrode of the compensation transistor are connected to the gate electrode of the drive transistor, and a second electrode of the compensation transistor is connected to the second electrode of the drive transistor.

In another aspect, the present disclosure also provides a display apparatus, including the display substrate described above.

In a further aspect, the present disclosure also provides a method for driving a display substrate, wherein the display substrate includes a plurality of circuit units constituting a plurality of unit rows and a plurality of unit columns, at least one circuit unit at least includes a pixel drive circuit and at least one control signal line, the pixel drive circuit at least includes a drive transistor, a first control transistor and a second control transistor, the first control transistor and the second control transistor are connected to the drive transistor respectively; the driving method at least includes a data writing stage and a light emitting stage, in the light emitting stage, in at least one pixel drive circuit of at least one unit row, turn-on and turn-off of the first control transistor are controlled by a control signal line in a previous unit row, and turn-on and turn-off of the second control transistor are controlled by a control signal line in the current unit row.

In an exemplary implementation, the pixel drive circuit further includes a first initialization transistor, a compensation transistor and an isolation transistor, a first electrode of the first initialization transistor is connected to a first initial signal line, a second electrode of the first initialization transistor and a first electrode of the compensation transistor are connected to a first electrode of the isolation transistor, a second electrode of the isolation transistor is connected to a gate electrode of the drive transistor, and a second electrode of the compensation transistor is connected to a second electrode of the drive transistor; the driving method further includes: turning on the isolation transistor at least twice prior to the data writing stage.

In an exemplary implementation, the driving method further includes a node reset stage between the data writing stage and the light emitting stage, and in the node reset stage, a first electrode and the second electrode of the drive transistor are reset.

Other aspects of the present disclosure may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are used to explain the technical solution of the present disclosure, and do not form limitations on the technical solution of the present disclosure.

FIG. 1 is a schematic diagram of a structure of a display apparatus.

FIG. 2 is a schematic diagram of a planar structure of a display substrate.

FIG. 3 is a schematic diagram of a sectional structure of a display substrate.

FIG. 4 is an equivalent circuit diagram of a pixel drive circuit according to an exemplary embodiment of the present disclosure.

FIG. 5A is a drive timing diagram of the pixel drive circuit shown in FIG. 4.

FIG. 5B is another drive timing diagram of the pixel drive circuit shown in FIG. 4.

FIG. 6 is a schematic diagram of a planar structure of a display substrate according to an exemplary embodiment of the present disclosure.

FIG. 7 is a schematic diagram of a display substrate after a pattern of a shielding layer is formed according to the present disclosure.

FIG. 8A and FIG. 8B are schematic diagrams of a display substrate after a pattern of a first semiconductor layer is formed according to the present disclosure.

FIGS. 9A and 9B are schematic diagrams of a display substrate after a pattern of a first conductive layer is formed, according to the present disclosure.

FIGS. 10A and 10B are schematic diagrams of a display substrate after a pattern of a second conductive layer is formed, according to the present disclosure.

FIG. 11A and FIG. 11B are schematic diagrams of a display substrate after a pattern of a second semiconductor layer is formed according to the present disclosure.

FIG. 12A and FIG. 12B are schematic diagrams of a display substrate after a pattern of a third conductive layer is formed, according to the present disclosure.

FIG. 13 is a schematic diagram of a display substrate after a pattern of a sixth insulating layer is formed according to the present disclosure.

FIG. 14A and FIG. 14B are schematic diagrams of a display substrate after a pattern of a fourth conductive layer is formed according to the present disclosure.

FIG. 15 is a schematic diagram of a display substrate after a pattern of a first planarization layer is formed according to the present disclosure.

FIG. 16A and FIG. 16B are schematic diagrams of a display substrate after a pattern of a fifth conductive layer is formed according to the present disclosure.

FIG. 17 is an equivalent circuit diagram of another pixel drive circuit according to an exemplary embodiment of the present disclosure.

FIG. 18 is a drive timing diagram of the pixel drive circuit shown in FIG. 17.

FIG. 19 is a schematic diagram of a planar structure of another display substrate according to an exemplary embodiment of the present disclosure.

FIG. 20 is a schematic diagram of another display substrate after a pattern of a first semiconductor layer is formed according to the present disclosure.

FIG. 21 is a schematic diagram of another display substrate after a pattern of a first conductive layer is formed according to the present disclosure.

FIG. 22 is a schematic diagram of another display substrate after a pattern of a second conductive layer is formed according to the present disclosure.

FIG. 23 is a schematic diagram of another display substrate after a pattern of a second semiconductor layer is formed according to the present disclosure.

FIG. 24 is a schematic diagram of another display substrate after a pattern of a third conductive layer is formed according to the present disclosure.

FIG. 25 is a schematic diagram of another display substrate after a pattern of a sixth insulating layer is formed according to the present disclosure.

FIG. 26 is a schematic diagram of another display substrate after a pattern of a fourth conductive layer is formed according to the present disclosure.

FIG. 27 is a schematic diagram of another display substrate after a pattern of a first planarization layer is formed according to the present disclosure.

FIG. 28 is a schematic diagram of another display substrate after a pattern of a fifth conductive layer is formed, according to the present disclosure.

FIG. 29 is a schematic diagram of a planar structure of yet another display substrate according to an exemplary embodiment of the present disclosure.

FIG. 30 is an equivalent circuit diagram of a still yet another pixel drive circuit according to an exemplary embodiment of the present disclosure.

Reference signs are described as follows.
11—first active layer; 12—second active layer; 13—third active layer; 14—fourth active layer; 15—fifth active layer; 16—sixth active layer; 17—seventh active layer; 18—eighth active layer; 19—ninth active layer; 21—first scan signal line; 22—second scan signal line 23—third scan signal line; 24—fourth scan signal line; 25—light emitting signal line; 31—first plate; 32—second plate; 33—first shielding line; 34—second shielding line; 41—first initial signal line; 42—second initial signal line; 43—third initial signal line; 51—first connection electrode; 52—second connection electrode; 53—third connection electrode; 54—fourth connection electrode; 55—fifth connection electrode; 56—sixth connection electrode; 57—seventh connection electrode; 58—eighth connection electrode; 59—ninth connection electrode; 60—tenth connection electrode; 61—first power supply line; 62—data signal line; 63—anode connection electrode; 101—substrate; 102—drive circuit layer; 103—light emitting structure layer; and 104—encapsulation structure layer.

### DETAILED DESCRIPTION

To make the objectives, technical solutions, and advantages of the present disclosure clearer, the embodiments of the present disclosure will be described in detail below with reference to the accompany drawings. It is to be noted that implementation modes may be implemented in multiple different forms. Those of ordinary skills in the art can easily understand such a fact that implementation modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulating film” may be replaced with an “insulating layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

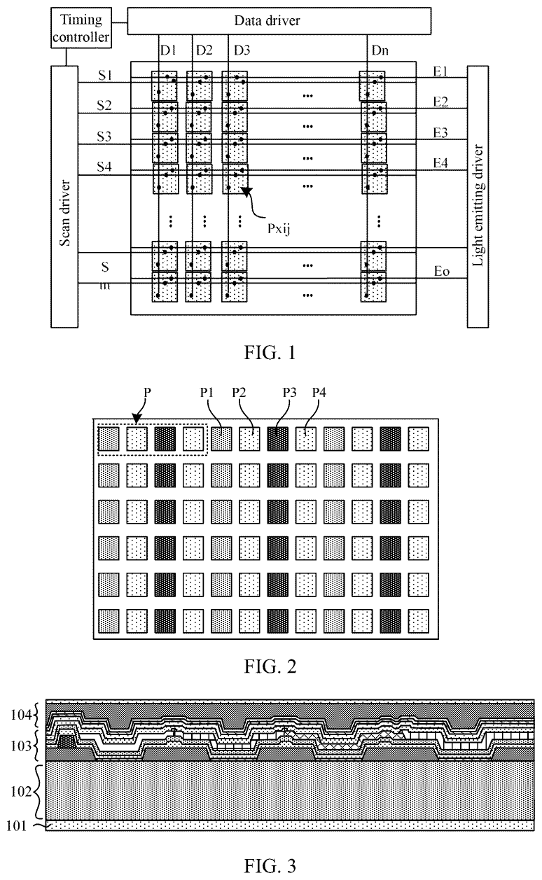

FIG. 1 is a schematic diagram of a structure of a display apparatus. As shown in FIG. 1, the display apparatus may include a timing controller, a data driver, a scan driver, a light emitting driver, and a pixel array. The timing controller is connected to the data driver, the scan driver, and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, the circuit unit may include, at least, a pixel drive circuit connected to a scan signal line, a light emitting signal line and a data signal line, respectively. The light emitting unit may include a light emitting device connected to the pixel drive circuit of the circuit unit. In an exemplary implementation, the timing controller may provide the data driver with a gray scale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the gray scale value using the clock signal and apply data voltages corresponding to the gray scale values to the data signal lines D1 to Dn by taking a pixel row as a unit, wherein n may be a natural number. The scan driver may generate scan signals to be provided to the scan signal lines S1, S2, S3, . . . , and Sm by receiving the clock signal and the scan start signal from the timing controller. For example, the scan driver may sequentially provide scan signals with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide emission signals with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be arranged on the display substrate.

FIG. 2 is a schematic diagram of a planar structure of a display substrate. As shown in FIG. 2, the display substrate may include a plurality of pixel units P arranged in a matrix, and at least one of the pixel units P may include a first sub-pixel P1, a second sub-pixel P2, a third sub-pixel P3, and a fourth sub-pixel P4. Each sub-pixel may include a circuit unit and a light emitting unit. The circuit unit may at least include a pixel drive circuit, the pixel drive circuit is connected to a scan signal line, a data signal line, and a light emitting signal line respectively, and is configured to receive a data voltage transmitted by the data signal line and output a corresponding current to the light emitting unit under control of the scan signal line and the light emitting signal line. The light emitting unit may include a light emitting device connected to a pixel drive circuit of a sub-pixel where the light emitting device is located, and the light emitting device is configured to emit light of a corresponding brightness in response to the current output by the pixel drive circuit of the sub-pixel where the light emitting device is located.

In an exemplary implementation, the first sub-pixels P1 may be red sub-pixels (R) emitting red light, the second sub-pixels P2 and the fourth sub-pixels P4 may be green sub-pixels (G) emitting green light, and the third sub-pixels P3 may be blue sub-pixels (B) emitting blue light. In an exemplary implementation, a sub-pixel may be in a shape of a rectangle, a rhombus, a pentagon, or a hexagon. Four sub-pixels may be arranged in a manner to stand side by side horizontally, in a manner to stand side by side vertically, or in a square arrangement, etc., which is not limited here in the present disclosure.

In an exemplary implementation, a pixel unit may include three sub-pixels, and the three sub-pixels may be arranged side by side horizontally, side by side vertically, or in an arrangement of a Chinese character “ [symbol] ”, which is not limited here in the present disclosure.

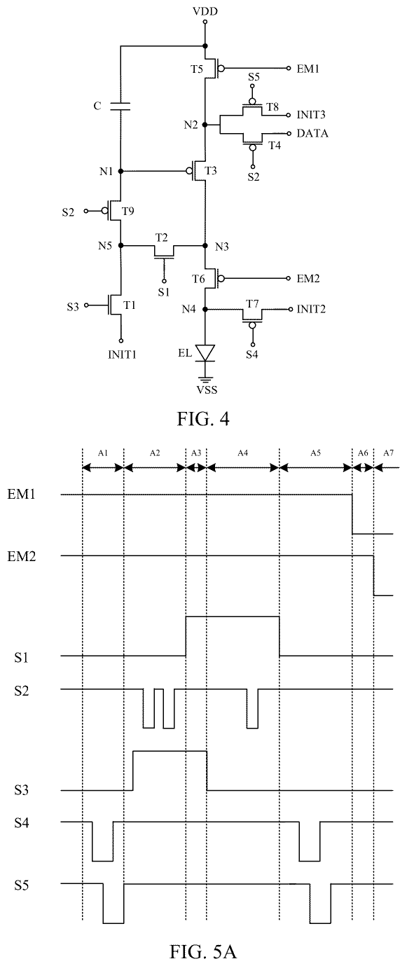

FIG. 3 is a schematic diagram of a sectional structure of a display substrate, illustrating a structure of four sub-pixels in a display region. As shown in FIG. 3, on a plane perpendicular to the display substrate, the display substrate may include a drive circuit layer 102 disposed on a substrate 101, a light emitting structure layer 103 disposed at a side of the drive circuit layer 102 away from the substrate 101, and an encapsulation structure layer 104 disposed at a side of the light emitting structure layer 103 away from the substrate 101. In some possible implementations, the display substrate may include another film layer, such as a touch structure layer, which is not limited here in the present disclosure.

In an exemplary implementation, the substrate 101 may be a flexible substrate, or may be a rigid substrate. The drive circuit layer 102 may include a plurality of circuit units, each of which may at least include a pixel drive circuit formed by a plurality of transistors and a storage capacitor. The light emitting structure layer 103 may include a plurality of light emitting units. Each light emitting unit may include a light emitting device. The light emitting device may at least include an anode, an organic emitting layer and a cathode. The anode is connected to a pixel drive circuit. The organic emitting layer is connected to the anode. The cathode is connected to the organic emitting layer. The organic emitting layer emits light of a corresponding color under driving of the anode and the cathode. The encapsulation layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of inorganic material/organic material/inorganic material and ensure that external moisture cannot enter the light emitting structure layer 103.

An exemplary implementation of the present disclosure provides a display substrate. In an exemplary implementation, on a plane perpendicular to the display substrate, the display substrate may include a drive structure layer arranged on a substrate and a light emitting structure layer arranged on a side of the drive structure layer away from the substrate. On a plane parallel to the display substrate, the drive structure layer may include a plurality of circuit units constituting a plurality of unit rows and a plurality of unit columns, and at least one of the circuit units may include a pixel drive circuit configured to output a corresponding current to a light emitting device connected to the pixel drive circuit. The light emitting structure layer may include a plurality of light emitting units, at least one of the light emitting units may include a light emitting device connected to a pixel drive circuit of the corresponding circuit unit. The light emitting device is configured to emit light of a corresponding brightness in response to a current output by the pixel drive circuit connected to the light emitting device.

In an exemplary implementation, the circuit units mentioned in the present disclosure refer to regions divided according to pixel drive circuits, and the light emitting units mentioned in the present disclosure refer to regions divided according to light emitting devices. In an exemplary implementation, a position and shape of an orthographic projection of a light emitting unit on the substrate may correspond to a position and shape of an orthographic projection of a circuit unit on the substrate, or the position and shape of the orthographic projection of the light emitting unit on the substrate may not correspond to the position and shape of the orthographic projection of the circuit unit on the substrate.

In an exemplary implementation, the display substrate of the present disclosure may include a plurality of circuit units constituting a plurality of unit rows and a plurality of unit columns, at least one circuit unit at least includes a pixel drive circuit, and at least one control signal line configured to provide a control signal to the pixel drive circuit to control turn-on and turn-off of transistors in the pixel drive circuit. In at least one circuit unit, the pixel drive circuit at least includes a drive transistor, a first control transistor and a second control transistor, the first control transistor and the second control transistor are connected to the drive transistor, respectively; and in at least one pixel drive circuit of at least one unit row, the first control transistor is connected to the control signal line in a previous unit row, and the second control transistor is connected to the control signal line in the current unit row.

In an exemplary implementation, the control signal line includes a light emitting signal line, the first control transistor includes a first light emitting control transistor, the second control transistor includes a second light emitting control transistor, a first electrode of the first light emitting control transistor is connected to a first power supply line, a second electrode of the first light emitting control transistor is connected to a first electrode of the drive transistor, and a first electrode of the second light emitting control transistor is connected to a second electrode of the drive transistor; in at least one pixel drive circuit of at least one unit row, a gate electrode of the first control transistor is connected to the light emitting signal line in a previous unit row, and a gate electrode of the second control transistor is connected to the light emitting signal line in the current unit row.

In an exemplary implementation, the control signal line includes a scan signal line, the first control transistor includes a third initialization transistor, the second control transistor includes a second initialization transistor, a first electrode of the second initialization transistor is connected to a second initial signal line, a second electrode of the second initialization transistor is connected to the second electrode of the drive transistor through the second light emitting control transistor, a first electrode of the third initialization transistor is connected to a third initial signal line, and a second electrode of the third initialization transistor is connected to the first electrode of the drive transistor; and in at least one pixel drive circuit of at least one unit row, a gate electrode of the third initialization transistor is connected to the scan signal line in a previous unit row, and a gate electrode of the second initialization transistor is connected to the scan signal line in the current unit row.

In an exemplary implementation, the pixel drive circuit further includes a first initialization transistor, a compensation transistor and an isolation transistor, a first electrode of the first initialization transistor is connected to a first initial signal line, a second electrode of the first initialization transistor and a first electrode of the compensation transistor are connected to a first electrode of the isolation transistor, a second electrode of the isolation transistor is connected to a gate electrode of the drive transistor, and a second electrode of the compensation transistor is connected to the second electrode of the drive transistor.

In another exemplary implementation, the pixel drive circuit further includes a first initialization transistor and a compensation transistor, a first electrode of the first initialization transistor is connected to a first initial signal line, a second electrode of the first initialization transistor and a first electrode of the compensation transistor are connected to the gate electrode of the drive transistor, and a second electrode of the compensation transistor is connected to the second electrode of the drive transistor.

A display substrate according to an exemplary embodiment of the present disclosure is illustrated below by some examples.

FIG. 4 is a schematic diagram of an equivalent circuit of a pixel drive circuit according to an exemplary embodiment of the present disclosure. As shown in FIG. 4, the pixel drive circuit is of a 9T1C structure, and may include nine transistors (a first transistor T1 to a ninth transistor T9) and one storage capacitor C. Each pixel drive circuit is connected to 12 signal lines (a first scan signal line S1, a second scan signal line S2, a third scan signal line S3, a fourth scan signal line S4, a fifth scan signal line S5, a first light emitting signal line EM1, a second light emitting signal line EM2, a first initial signal line INIT1, a second initial signal line INIT2, a third initial signal line INIT3, a data signal line DATA and a first power supply line VDD), respectively.

In an exemplary implementation, each pixel drive circuit may include a first node N1, a second node N2, a third node N3, a fourth node N4 and a fifth node N5. The first node N1 is connected to a gate electrode of the third transistor T3, a second electrode of the ninth transistor T9 and a first terminal of the storage capacitor C, respectively. The second node N2 is connected to a first electrode of the third transistor T3, a second electrode of the fourth transistor T4, a second electrode of the fifth transistor T5 and a second electrode of the eighth transistor T8, respectively. The third node N3 is connected to a second electrode of the second transistor T2, a second electrode of the third transistor T3 and a first electrode of the sixth transistor T6, respectively. The fourth node N4 is connected to a second electrode of the sixth transistor T6 and a second electrode of the seventh transistor T7, respectively. The fifth node N5 is connected to a second electrode of the first transistor T1, a first electrode of the second transistor T2 and a first electrode of the ninth transistor T9, respectively. The fourth node N4 is also connected to a first electrode of the light emitting device EL.

In an exemplary implementation, the first terminal of the storage capacitor C in the pixel drive circuit is connected to the first node N1, and a second terminal of the storage capacitor C is connected to the first power supply line VDD.

In an exemplary implementation, the first transistor T1 may be referred to as a first initialization transistor. A gate electrode of the first transistor T1 is connected to the third scan signal line S3, a first electrode of the first transistor T1 is connected to the first initial signal line INIT1, and the second electrode of the first transistor T1 is connected to the fifth node N5.

In an exemplary implementation, the second transistor T2 may be referred to as a compensation transistor. A gate electrode of the second transistor T2 is connected to the first scan signal line S1, the first electrode of the second transistor T2 is connected to the fifth node N5, and the second electrode of the second transistor T2 is connected to the third node N3.

In an exemplary implementation, the third transistor T3 may be referred to as a drive transistor. The gate electrode of the third transistor T3 is connected to the first node N1, the first electrode of the third transistor T3 is connected to the second node N2, and the second electrode of the third transistor T3 is connected to the third node N3.

In an exemplary implementation, the fourth transistor T4 may be referred to as a data writing transistor. A gate electrode of the fourth transistor T4 is connected to the second scan signal line S2, a first electrode of the fourth transistor T4 is connected to the data signal line DATA, and the second electrode of the fourth transistor T4 is connected to the second node N2.

In an exemplary implementation, the fifth transistor T5 may be referred to as a first light emitting control transistor. A gate electrode of the fifth transistor T5 is connected to the first light emitting signal line EM1, a first electrode of the fifth transistor T5 is connected to the first power supply line VDD, and the second electrode of the fifth transistor T5 is connected to the second node N2.

In an exemplary implementation, the sixth transistor T6 may be referred to as a second light emitting control transistor. A gate electrode of the sixth transistor T6 is connected to the second light emitting signal line EM2, the first electrode of the sixth transistor T6 is connected to the third node N3, and the second electrode of the sixth transistor T6 is connected to the fourth node N4.

In an exemplary implementation, the seventh transistor T7 may be referred to as a second initialization transistor. A gate electrode of the seventh transistor T7 is connected to the fourth scan signal line S4, a first electrode of the seventh transistor T7 is connected to the second initial signal line INIT2, and the second electrode of the seventh transistor T7 is connected to the fourth node N4.

In an exemplary implementation, the eighth transistor T8 may be referred to as a third initialization transistor. A gate electrode of the eighth transistor T8 is connected to the fifth scan signal line S5, a first electrode of the eighth transistor T8 is connected to the third initial signal line INIT3, and the second electrode of the eighth transistor T8 is connected to the second node N2.

In an exemplary implementation, a gate electrode of the ninth transistor T9 is connected to the second scan signal line S2, the first electrode of the ninth transistor T9 is connected to the fifth node N5, and the second electrode of the ninth transistor T9 is connected to the first node N1.

In an exemplary implementation, the first electrode of the light emitting device EL is connected to the fourth node N4, and a second electrode of the light emitting device EL is connected to the second power supply line VSS. The light emitting device EL may be an OLED including a first electrode (an anode), an organic light emitting layer, and a second electrode (a cathode) which are stacked, or may be a QLED including a first electrode, a quantum dot light emitting layer, and a second electrode which are stacked.

In an exemplary implementation, a signal of the first power supply line VDD is a high-level signal continuously provided, and a signal of the second power supply line VSS is a low-level signal continuously provided.

In some possible exemplary implementations, the first transistor T1 to the ninth transistor T9 in the pixel drive circuit may be P-type transistors or may be N-type transistors. In some other possible exemplary implementations, the first transistor T1 to the ninth transistor T9 in the pixel drive circuit may include P-type transistors and N-type transistors.

In an exemplary implementation, the first transistor T1 to the ninth transistor T9 in the pixel drive circuit may be low-temperature polysilicon transistors, or may be oxide transistors, or may be low-temperature polysilicon transistors and oxide transistors. An active layer of a low temperature polysilicon transistor is made of Low Temperature Poly-Silicon (LTPS), and an active layer of an oxide transistor is made of an oxide semiconductor (Oxide). The low temperature polysilicon transistor has advantages such as a high migration rate and fast charging, and the oxide transistor has advantages such as a low drain current. The low temperature polysilicon transistor and the oxide transistor are integrated on one display substrate to form a Low Temperature Polycrystalline Oxide (LTPO) display substrate, such that advantages of the low temperature polysilicon transistor and the oxide transistor may be utilized, low-frequency drive can be achieved, power consumption can be reduced, and display quality can be improved.

As shown in FIG. 4, in this exemplary embodiment, the first transistor T1 and the second transistor T2 in the pixel drive circuit may be oxide transistors (N-type transistors), and the third transistor T3 to the ninth transistor T9 may be low temperature polysilicon transistors (P-type transistors).

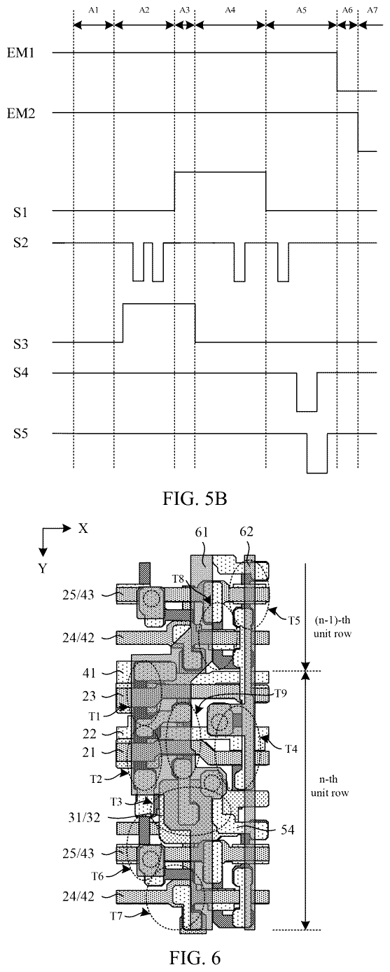

FIG. 5A is a drive timing diagram of the pixel drive circuit shown in FIG. 4. As shown in FIG. 5A, in an exemplary implementation, the working process of the pixel drive circuit may include the following stages.

A first stage A1 may be referred to as a reset stage for the second node N2 and the fourth node N4. In the first stage A1, signals of the first scan signal line S1, the third scan signal line S3, the fourth scan signal line S4 and the fifth scan signal line S5 are low-level signals, and signals of the second scan signal line S2, the first light emitting signal line EM1 and the second light emitting signal line EM2 are high-level signals, so that the seventh transistor T7 and the eighth transistor T8 are turned on, and the other transistors are turned off.

The seventh transistor T7 is turned on, so that the signal of the second initial signal line INIT2 is provided to the fourth node N4, to initialize (reset) the first electrode of the light emitting device EL and clear original charges in the first electrode of the light emitting device EL, thereby the potential of the fourth node N4 is Vinit2. The eighth transistor T8 is turned on, so that the signal of the third initial signal line INIT3 is provided to the second node N2, and the second node N2 is initialized (reset), thereby the potential of the second node N2 is Vinit3.

The second stage A2 may be referred to as a reset stage for the first node N1. In the second stage A2, the signal of the first scan signal line S1 is a low-level signal, the signal of the second scan signal line S2 is a high-level signal, except two occurrences of a low-level signal, and the signals of the third scan signal line S3, the fourth scan signal line S4, the fifth scan signal line S5, the first light emitting signal line EM1 and the second light emitting signal line EM2 are high-level signals, so that the first transistor T1 is turned on, the fourth transistor T4 and the ninth transistor T9 are turned on twice, and the other transistors are turned off.

The first transistor T1 is turned on, so that the signal of the first initial signal line INIT1 is provided to the fifth node N5. When the fourth transistor T4 and the ninth transistor T9 are turned on, the signal of the first initial signal line INIT1 is provided to the first node N1 to initialize (reset) the first node N1 and clear original charges in the first node N1, and the potential of the first node N1 is Vinit1. The ninth transistor T9 is a low temperature polysilicon transistor, before the ninth transistor T9 is turned on for the first time, it will be affected by the potential of the first node N1 and a gate bias voltage, and the potential of the first node N1 is related to the data voltage in the previous stage, so the characteristics of the ninth transistor T9 are affected by the previous stage. After the ninth transistor T9 is turned on for the first time, the potential of the first node N1 is reset as Vinit1, and the gate voltage of the ninth transistor T9 is relatively fixed regardless of whether it is a high level or a low level. Therefore, after the first turn-on and turn-off, the influence of data in the previous stage on the characteristics of the ninth transistor T9 can be eliminated. When the ninth transistor T9 is turned on for the second time, the potential of the first node N1 is reset again as Vinit1. In the present disclosure, by continuously resetting the first node N1 twice, the influence of the data voltage in the previous stage on the characteristics of the ninth transistor T9 can be better eliminated, thereby improving image sticking and low grayscale image quality. In addition, since the fourth transistor T4 is turned on twice in this stage, the data signal line DATA writes data voltages of previous several unit rows to the second node N2, and the potential of the second node N2 is changed, so that the gate-source voltage of the third transistor T3 is changed, and the characteristics of the third transistor T3 are reset, which can improve image sticking.

A third stage A3 may be referred to as a reset stage for the third node N3. In the third stage A3, the signals of the first scan signal line S1, the second scan signal line S2, the third scan signal line S3, the fourth scan signal line S4, the fifth scan signal line S5, the first light emitting signal line EM1 and the second light emitting signal line EM2 are high-level signals, so that the first transistor T1 and the second transistor T2 are turned on, and the other transistors are turned off.

The second transistor T2 is turned on, so that the third node N3 and the fifth node N5 are turned on, and the first transistor T1 is turned on, so that the signal of the first initial signal line INIT1 is provided to the third node N3 to initialize (reset) the third node N3 and clear original charges in the third node N3, thereby the potential of the third node N3 is Vinit1.

A fourth stage A4 may be referred to as a data writing stage. The signal of the third scan signal line S3 is a low-level signal, the signal of the second scan signal line S2 is a low-level signal for a short period of time, and the signals of the first scan signal line S1, the fourth scan signal line S4, the fifth scan signal line S5, the first light emitting signal line EM1 and the second light emitting signal line EM2 are high-level signals, so that the second transistor T2, the fourth transistor T4 and the ninth transistor T9 are turned on, and the other transistors are turned off.

The second transistor T2 is turned on, so that the third node N3 and the fifth node N5 are turned on, and the ninth transistor T9 is turned on, so that the first node N1 and the fifth node N5 are turned on. Since the third transistor T3 is continuously turned on in this stage, the fourth transistor T4 is turned on, so that the data signal output from the data signal line DATA is provided to the first node N1 through the second node N2, the turned-on third transistor T3, the third node N3, the turned-on second transistor T2, the fifth node N5 and the turned-on ninth transistor T9, and a difference between the data voltage output from the data signal line DATA and a threshold voltage of the third transistor T3 is charged to the storage capacitor C. The voltage of the first node N1 is Vd1−|Vth|, wherein Vd is the data voltage output from the data signal line DATA, and Vth is the threshold voltage of the third transistor T3. When the ninth transistor T9 is turned off, the storage capacitor C maintains the data voltage.

A fifth stage A5 may be referred to as a reset stage for the second node N2, the third node N3 and the fourth node N4. In the fifth stage A5, the signals of the first scan signal line S1 and the third scan signal line S3 are low-level signals, the signals of the fourth scan signal line S4 and the fifth scan signal line S5 are low-level signals in sequence in a short period of time, and the signals of the second scan signal line S2, the first light emitting signal line EM1 and the second light emitting signal line EM2 are high-level signals, so that the seventh transistor T7 and the eighth transistor T8 are turned on, and the other transistors are turned off.

The seventh transistor T7 is turned on, so that the signal of the second initial signal line INIT2 is provided to the fourth node N4, and since in this stage, the third transistor T3 is continuously turned on, the eighth transistor T8 is turned on, so that the signal of the third initial signal line INIT3 is provided to the second node N2 and the third node N3, to reset the second node N2, the third node N3 and the fourth node N4, respectively, and the potentials of the second node N2 and the third node N3 are Vinit3, and the potential of the fourth node N4 is Vinit2. In this stage, the second node N2, the third node N3 and the fourth node N4 are reset, which can alleviate hysteresis bias due to a difference in gray scales between adjacent pixels, reduce the hysteresis bias, and also periodically reset the anode of the OLED to improve the low-frequency flickering.

A sixth stage A6 may be referred to as a reset stage for the second node N2 and the third node N3. In the sixth stage A6, the signals of the first scan signal line S1, the third scan signal line S3 and the first light emitting signal line EM1 are low-level signals, and the signals of the second scan signal line S2, the fourth scan signal line S4, the fifth scan signal line S5 and the second light emitting signal line EM2 are high-level signals, so that the fifth transistor T5 is turned on, and the other transistors are turned off.

The fifth transistor T5 is turned on, so that the power supply voltage Vdd output from the first power supply line VDD is provided to the second node N2 and the third node N3 to reset the second node N2 and the third node N3, i.e., to reset the first electrode and the second electrode of the third transistor T3.

A seventh stage A7 may be referred to as a light emitting stage. In the seventh stage A7, the signals of the first scan signal line S1, the third scan signal line S3, the first light emitting signal line EM1 and the second light emitting signal line EM2 are low-level signals, and the signals of the second scan signal line S2, the fourth scan signal line S4 and the fifth scan signal line S5 are high-level signals, so that the fifth transistor T5 and the sixth transistor T6 are turned on, and the other transistors are turned off.

The fifth transistor T5 and the sixth transistor T6 are turned on, so that a power supply voltage outputted from the first power supply line VDD provides a driving voltage to a first electrode of the light emitting device EL through the turned-on fifth transistor T5, third transistor T3 and sixth transistor T6 to drive the light emitting device EL to emit light.

In a driving process of the pixel drive circuit, a driving current flowing through the third transistor T3 (a drive transistor) of each pixel drive circuit is determined by a voltage difference between a gate electrode and a first electrode of the third transistor T3. Since the voltage of the first node N1 is Vd−|Vth|, the driving current of the third transistor T3 is as follows:

$$I = K * {( Vgs - V t h )}^{2} = K * {[ ( Vdd - Vd + \vert Vth \vert ) - Vth ]}^{2} = K * {[ ( Vdd - Vd ]}^{2}$$

Herein I is the driving current flowing through the third transistor T3, i.e., a driving current for driving the light emitting device EL, K is a constant related to process and design, and Vgs is the voltage difference between the gate electrode and the first electrode of the third transistor T3.

It can be seen from the derivation results of the above current formula that in the light emitting stage, the driving current of the third transistor T3 of each pixel drive circuit is not affected by the threshold voltage of the third transistor T3. Therefore, the influence of the threshold voltage of the third transistor T3 on the driving current is eliminated, which can ensure uniformity of the display brightness of the display product, and improve the overall display effect of the display product.

FIG. 5B is another drive timing diagram of the pixel drive circuit shown in FIG. 4. As shown in FIG. 5B, in an exemplary implementation, the working process of the pixel drive circuit is substantially the same as that in FIG. 5A, except that the signals of the fourth scan signal line S4 and the fifth scan signal line S5 in the first stage A1 are high-level signals, the seventh transistor T7 and the eighth transistor T8 are turned off, and the second node N2 and the fourth node N4 are not reset in this stage; in the fifth stage A5, before the seventh transistor T7 and the eighth transistor T8 are turned on, the signal of the second scan signal line S2 is a low-level signal for a short period of time, the fourth transistor T4 and the ninth transistor T9 are turned on again, the fourth transistor T4 is turned on, so that the data voltage of the next unit row resets the second node N2 and the third node N3, and the ninth transistor T9 is turned on, so that the first node N1 and the fifth node N5 are turned on, after the charges of the two nodes are neutralized, there is no potential difference between the two nodes.

FIG. 6 is a schematic diagram of a planar structure of a display substrate according to an exemplary embodiment of the present disclosure. In an exemplary implementation, the display substrate may include a plurality of circuit units, the plurality of circuit units may form a plurality of unit rows and a plurality of unit columns, the plurality of circuit units in each unit row are sequentially arranged along the first direction X, and the plurality of unit rows are sequentially arranged along a second direction Y, constituting a circuit unit array arranged in an array, and the first direction X and the second direction Y intersect.

As shown in FIG. 6, at least one circuit unit may include a pixel drive circuit, and a first scan signal line 21, a second scan signal line 22, a third scan signal line 23, a fourth scan signal line 24, a light emitting signal line 25, a first initial signal line 41, a second initial signal line 42, a third initial signal line 43, a first power supply line 61, and a data signal line 62 that are connected to the pixel drive circuit. In an exemplary implementation, main body portions of the first scan signal line 21, the second scan signal line 22, the third scan signal line 23, the fourth scan signal line 24, the light emitting signal line 25, the first initial signal line 41, the second initial signal line 42, and the third initial signal line 43 may be in a shape of a straight line or a polyline extending in the first direction X, and main body portions of the first power supply line 61 and the data signal line 62 may be in a shape of a straight line or a polyline extending in the second direction Y.

In the present disclosure, “A extends along a B direction” refers to that A may include a main body portion and a secondary body portion connected to the main body portion, wherein the main body portion is a line, a line segment, or a strip-shaped body, the main body portion extends along the B direction, and a length of the main body portion extending along the B direction is greater than a length of the secondary body portion extending along another direction. In following description, “A extends along a B direction” means “a main body portion of A extends along the B direction”.

In an exemplary implementation, at least one pixel drive circuit may at least include a storage capacitor and a plurality of transistors, the storage capacitor may include a first plate and a second plate which are stacked, and the plurality of transistors may include a first transistor T1 as a first initialization transistor, a second transistor T2 as a compensation transistor, a third transistor T3 as a drive transistor, a fourth transistor T4 as a data writing transistor, a fifth transistor T5 as a first light emitting control transistor, a sixth transistor T6 as a second light emitting control transistor, a seventh transistor T7 as a second initialization transistor, an eighth transistor T8 as a third initialization transistor, and a ninth transistor T9 as an isolation transistor. The first transistor T1 and the second transistor T2 are oxide transistors, and the third transistor T3 to the ninth transistor T9 are low-temperature polysilicon transistors.

In an exemplary implementation, a first electrode of the first transistor T1 is connected to the first initial signal line 41, a first electrode of the fourth transistor T4 is connected to the data signal line 62, a first electrode of the fifth transistor T5 is connected to the first power supply line 61, a first electrode of the seventh transistor T7 is connected to the second initial signal line 42, and a first electrode of the eighth transistor T8 is connected to the third initial signal line 43. A second electrode of the first transistor T1 and a first electrode of the second transistor T2 are connected to a first electrode of the ninth transistor T9, a second electrode of the ninth transistor T9 is connected to a gate electrode of the third transistor T3 (a first plate of the storage capacitor), a second electrode of the fourth transistor T4, a second electrode of the fifth transistor T5 and a second electrode of the eighth transistor T8 are connected to a first electrode of the third transistor T3, a second electrode of the second transistor T2 and a first electrode of the sixth transistor T6 are connected to a second electrode of the third transistor T3, and a second electrode of the sixth transistor T6 is connected to a second electrode of the seventh transistor T7.

In an exemplary implementation, in at least one pixel drive circuit of at least one unit row, a gate electrode of the fifth transistor T5 is connected to the light emitting signal line 25 in the previous unit row, and a gate electrode of the sixth transistor T6 is connected to the light emitting signal line 25 in the current unit row. For example, the gate electrode of the fifth transistor T5 of the pixel drive circuit in an n-th unit row is connected to the light emitting signal line 25 in an (n−1)-th unit row, and the gate electrode of the sixth transistor T6 of the pixel drive circuit in the n-th unit row is connected to the light emitting signal line 25 in the n-th unit row. As another example, the gate electrode of the fifth transistor T5 of the pixel drive circuit in an (n+1)-th unit row is connected to the light emitting signal line 25 in the n-th unit row, and the gate electrode of the sixth transistor T6 of the pixel drive circuit in the (n+1)-th unit row is connected to the light emitting signal line 25 in the (n+1)-th unit row. In an exemplary implementation, the light emitting signal line 25 may serve as a control signal line in the present disclosure, the fifth transistor T5 may serve as a first control transistor in the present disclosure, and the sixth transistor T6 may serve as a second control transistor in the present disclosure, n being a positive integer greater than 1.

In an exemplary implementation, in at least one pixel drive circuit, the fifth transistor T5 and the sixth transistor T6 connected to the same third transistor T3 may be arranged on two sides of the third transistor T3 in the second direction Y (the unit column direction), respectively. For example, in a pixel drive circuit of the n-th unit row, the fifth transistor T5 may be arranged on a side of the third transistor T3 in the opposite direction of the second direction Y, and the sixth transistor T6 may be arranged on a side of the third transistor T3 in the second direction Y.

In an exemplary implementation, the fifth transistor T5 may at least include a fifth active layer, the sixth transistor T6 may at least include a sixth active layer, the fifth active layer may serve as a first light emitting control active layer in the present disclosure, and the sixth active layer may serve as a second light emitting control active layer in the present disclosure. In at least one pixel drive circuit of at least one unit row, the fifth active layer may be arranged in a circuit unit of the previous unit row, and the sixth active layer may be arranged in a circuit unit of the current unit row. For example, in a pixel drive circuit of the n-th unit row, the fifth active layer may be arranged in a circuit unit of the (n−1)-th unit row, and the sixth active layer may be arranged in a circuit unit of the n-th unit row.

In an exemplary implementation, in at least one pixel drive circuit of at least one unit row, the fifth active layer may be arranged on a side of the sixth active layer of a pixel drive circuit in the previous unit row in the first direction X (the unit row direction). For example, in a pixel drive circuit of the n-th unit row, the fifth active layer may be arranged on a side of the sixth active layer of a pixel drive circuit in the (n−1)-th unit row in the first direction X.

In an exemplary implementation, the pixel drive circuit may further include a storage capacitor and a power supply connection electrode 54, the storage capacitor may include a first plate 31 and a second plate 32, and an orthographic projection of the first plate 31 on a plane of the display substrate overlaps at least partially with an orthographic projection of the second plate 32 on the plane of the display substrate. In at least one pixel drive circuit of at least one unit row, a first terminal of the power supply connection electrode 54 is connected to a first region of the fifth active layer of a pixel drive circuit in the next unit row, and a second terminal of the power supply connection electrode 54 is connected to the second plate 32 of a pixel drive circuit in the current unit row. For example, in a pixel drive circuit of the n-th unit row, the first terminal of the power supply connection electrode 54 is connected to the first region of the fifth active layer of a pixel drive circuit in the (n+1)-th unit row, and the second terminal of the power supply connection electrode 54 is connected to the second plate 32 of a pixel drive circuit in the n-th unit row.

In an exemplary implementation, in at least one pixel drive circuit of at least one unit row, a gate electrode of the eighth transistor T8 is connected to a fourth scan signal line 24 in the previous unit row, and a gate electrode of the seventh transistor T7 is connected to a fourth scan signal line 24 in the current unit row. For example, the gate electrode of the eighth transistor T8 of a pixel drive circuit in the n-th unit row is connected to a fourth scan signal line 24 in the (n−1)-th unit row, and the gate electrode of the seventh transistor T7 of a pixel drive circuit in the n-th unit row is connected to a fourth scan signal line 24 in the n-th unit row. For another example, the gate electrode of the eighth transistor T8 of a pixel drive circuit in the (n+1)-th unit row is connected to a fourth scan signal line 24 in the n-th unit row, and the gate electrode of the seventh transistor T7 of a pixel drive circuit in the (n+1)-th unit row is connected to a fourth scan signal line 24 in the (n+1)-th unit row. In an exemplary implementation, the fourth scan signal line 24 may serve as another control signal line in the present disclosure, the eighth transistor T8 may serve as another first control transistor in the present disclosure, and the seventh transistor T7 may serve as another second control transistor in the present disclosure.

In an exemplary implementation, in at least one pixel drive circuit, the seventh transistor T7 and the eighth transistor T8 connected to the same third transistor T3 may be arranged on two sides of the third transistor T3 in the second direction Y, respectively. For example, in a pixel drive circuit of the n-th unit row, the eighth transistor T8 may be arranged on a side of the third transistor T3 in the opposite direction of the second direction Y, and the seventh transistor T7 may be arranged on a side of the third transistor T3 in the second direction Y.

In an exemplary implementation, the seventh transistor T7 may at least include a seventh active layer, the eighth transistor T8 may at least include an eighth active layer, the seventh transistor T7 may serve as a second initialization active layer in the present disclosure, and the eighth active layer may serve as a third initialization active layer in the present disclosure. In at least one pixel drive circuit of at least one unit row, the eighth active layer may be arranged in a circuit unit of the previous unit row, and the seventh active layer may be arranged in a circuit unit of the current unit row. For example, in a pixel drive circuit of the n-th unit row, the eighth active layer may be arranged in a circuit unit of the (n−1)-th unit row, and the seventh active layer may be arranged in a circuit unit of the n-th unit row.

In an exemplary implementation, in at least one pixel drive circuit of at least one unit row, the eighth active layer may be arranged on a side of the seventh active layer of a pixel drive circuit in the previous unit row in the first direction X (the unit row direction). For example, in a pixel drive circuit of the n-th unit row, the eighth active layer may be arranged on a side of the seventh active layer of a pixel drive circuit in the (n−1)-th unit row in the first direction X.

In an exemplary implementation, in at least one pixel drive circuit of at least one unit row, a first region of the seventh active layer is connected to a second initial signal line 42 in the current unit row, and a first region of the eighth active layer is connected to a third initial signal line 43 in the previous unit row. For example, in a pixel drive circuit of the n-th unit row, the first region of the seventh active layer is connected to a second initial signal line 42 in the n-th unit row, and the first region of the eighth active layer is connected to a third initial signal line 43 in the (n−1)-th unit row.

In an exemplary implementation, in a direction perpendicular to the display substrate, the display substrate may include a first semiconductor layer arranged on a substrate, a first conductive layer arranged on a side of the first semiconductor layer away from the substrate, a second conductive layer arranged on a side of the first conductive layer away from the substrate, a second semiconductor layer arranged on a side of the second conductive layer away from the substrate, a third conductive layer arranged on a side of the second semiconductor layer away from the substrate, a fourth conductive layer arranged on a side of the third conductive layer away from the substrate, and a fifth conductive layer arranged on a side of the fourth conductive layer away from the substrate. The first semiconductor layer may at least include active layers of the third transistor T3 to the ninth transistor T9. The first conductive layer may at least include a second scan signal line 22, a fourth scan signal line 24, a light emitting signal line 25, a first initial signal line 41 and a first plate 31 of the storage capacitor. The second conductive layer may at least include a second plate 32 of the storage capacitor. The second semiconductor layer may at least include active layers of the first transistor T1 and the second transistor T2. The third conductive layer may at least include a first scan signal line 21, a third scan signal line 23, a second initial signal line 42 and a third initial signal line 43. The fourth conductive layer may at least include a plurality of connection electrodes; and the fifth conductive layer may at least include a first power supply line 61 and a data signal line 62.

In an exemplary implementation, an orthographic projection of the second initial signal line 42 on the substrate overlaps at least partially with an orthographic projection of the fourth scan signal line 24 on the substrate.

In an exemplary implementation, an orthographic projection of the third initial signal line 43 on the substrate overlaps at least partially with an orthographic projection of the light emitting signal line 25 on the substrate.

Exemplary description is made below through a preparation process of a display substrate. A “patterning process” mentioned in the present disclosure includes a treatment such as deposition of a film layer, photoresist coating on a film layer, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

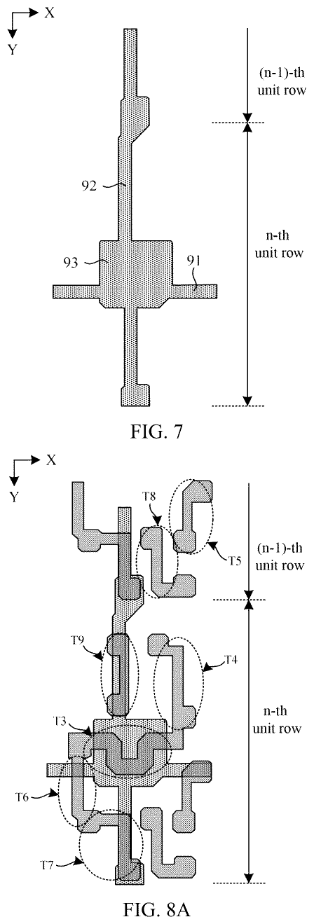

In an exemplary implementation, taking one circuit unit as an example, the manufacturing process of the display substrate in this embodiment may include the following operations.
(1) A pattern of a shielding layer is formed. In an exemplary implementation, forming the pattern of the shielding layer may include: depositing a shielding thin film on a substrate, patterning the shielding thin film through a patterning process to form the pattern of the shielding layer on the substrate, as shown in FIG. 7. In an exemplary implementation, the shielding layer may be referred to as a bottom shielding metal (BSM) layer.

In an exemplary implementation, the pattern of the shielding layer in each circuit unit may at least include a first shielding connection line 91, a second shielding connection line 92 and a shielding electrode 93.

In an exemplary implementation, the shielding electrode 93 may be in a shape of a rectangle, corners of the rectangle may be provided with chamfers. The first shielding connection line 91 may be in a shape of a straight line or a polyline extending in the first direction X. The first shielding connection lines 91 may be arranged on two sides of the shielding electrode 93 in the first direction X and connected to the shielding electrode 93, respectively. The second shielding connection line 92 may be in a shape of a straight line or a polyline extending in the second direction Y. The second shielding connection lines 92 may be arranged on two sides of the shielding electrode 93 in the second direction Y, and connected to the shielding electrode 93, respectively.

In an exemplary implementation, in a unit row, the first shielding connection lines 91 in two adjacent circuit units in the first direction X may be connected to each other to form an integrated structure. And/or, in a unit column, the second shielding connection lines 92 in two adjacent circuit units in the second direction Y may be connected to each other to form an integrated structure. The shielding layers in unit rows and unit columns are connected as a whole, which can ensure that the shielding layers in the display substrate have the same potential, and is beneficial to improving uniformity of a panel, avoiding poor display of the display substrate, and ensuring the display effect of the display substrate.

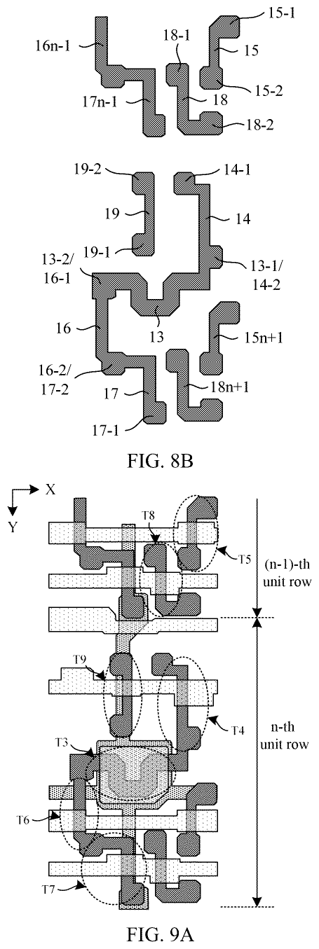

In an exemplary implementation, the first shielding connection lines 91 on both sides of the shielding electrode 93 may be located on a straight line extending in the first direction X, and the second shielding connection lines 92 on both sides of the shielding electrode 93 may be staggered in the first direction X, which is not limited herein in the present disclosure.
(2) A pattern of a first semiconductor layer is formed. In an exemplary implementation, forming the pattern of the first semiconductor layer may include: sequentially depositing a first insulating thin film and a first semiconductor thin film on the substrate on which the aforementioned pattern is formed, and patterning the first semiconductor thin film through a patterning process to form a first insulating layer covering the shielding layer, and a pattern of a first semiconductor layer arranged on the first insulating layer, as shown in FIG. 8A and FIG. 8B. FIG. 8B is a schematic plan view of the first semiconductor layer in FIG. 8A.

In an exemplary implementation, the pattern of the first semiconductor layer in each circuit unit may at least include the third active layer 13 of the third transistor T3 to the ninth active layer 19 of the ninth transistor T9, the third active layer 13, the fourth active layer 14, the sixth active layer 16 and the seventh active layer 17 are connected to each other to form an integrated structure, and the fifth active layer 15, the eighth active layer 18 and the ninth active layer 19 are arranged separately.

In an exemplary implementation, an orthographic projection of the third active layer 13 on the substrate overlaps at least partially with an orthographic projection of the shielding electrode 93 on the substrate, and the shielding electrode 93 acts as a shielding layer of the third transistor T3 to shield the channel region of the third transistor T3, thereby ensuring the electrical performance of the third transistor T3.

In an exemplary implementation, in the pixel drive circuit of the current circuit unit, in the first direction X, the fourth active layer 14, the fifth active layer 15 and the eighth active layer 18 may be located on a side of the third active layer 13 in the current circuit unit in the first direction X, and the sixth active layer 16 may be located on a side of the third active layer 13 in the current circuit unit in the opposite direction of the first direction X. In the second direction Y, the sixth active layer 16 and the seventh active layer 17 may be located on a side of the third active layer 13 in the current circuit unit in the second direction Y, and the fourth active layer 14, the fifth active layer 15, the eighth active layer 18 and the ninth active layer 19 may be located on a side of the third active layer 13 in the current circuit unit in the opposite direction of the second direction Y.

In an exemplary implementation, the ninth active layer 19 may be located on a side of the fourth active layer 14 in the opposite direction of the first direction X.

In an exemplary implementation, the third active layer 13 may be in a shape of an inverted character “Ω”, main body portions of the fourth active layer 14, the fifth active layer 15, the sixth active layer 16 and the ninth active layer 19 may be in a shape of a strip extending in the second direction Y, and the seventh active layer 17 and the eighth active layer 18 may be in a shape of a character “L”.

In an exemplary implementation, the third active layer 13 to the ninth active layer 19 may each include a first region, a second region, and a channel region located between the first region and the second region. In an exemplary implementation, the first region 13-1 of the third active layer is connected to the second region 14-2 of the fourth active layer, and the first region 13-1 of the third active layer may serve as the second region 14-2 of the fourth active layer. The second region 13-2 of the third active layer is connected to the first region 16-1 of the sixth active layer, and the second region 13-2 of the third active layer may serve as the first region 16-1 of the sixth active layer. The second region 16-2 of the sixth active layer is connected to the second region 17-2 of the seventh active layer, and the second region 16-2 of the sixth active layer may serve as the second region 17-2 of the seventh active layer. The first region 14-1 of the fourth active layer, the first region 15-1 of the fifth active layer, the second region 15-2 of the fifth active layer, the first region 17-1 of the seventh active layer, the first region 18-1 of the eighth active layer, the second region 18-2 of the eighth active layer, the first region 19-1 of the ninth active layer and the second region 19-2 of the ninth active layer may be arranged separately.

In an exemplary implementation, in a unit column, the fifth active layer 15 and the eighth active layer 18 of the pixel drive circuit in the current circuit unit may be arranged in a circuit unit of the previous unit row, and the third active layer 13, the fourth active layer 14, the sixth active layer 16, the seventh active layer 17 and the ninth active layer 19 may be arranged in the current circuit unit.

In an exemplary implementation, the fifth active layer 15 of the pixel drive circuit in a circuit unit of the current unit row may be located on a side of the sixth active layer 16 of the pixel drive circuit in a circuit unit of the previous unit row in the first direction X, so that the fifth active layer 15 and the sixth active layer 16 respectively in the two unit rows may share one light emitting signal line, and this light emitting signal line can simultaneously control the turn-on and turn-off of the sixth transistor T6 of the current unit row and the fifth transistor T5 of the next unit row. For example, the fifth active layer 15 of a pixel drive circuit in the n-th unit row is arranged in a circuit unit of the (n−1)-th unit row, so that the fifth active layer 15 of the pixel drive circuit in the n-th unit row and the sixth active layer 16n-1 of the pixel drive circuit in the (n−1)-th unit row may share one light emitting signal line, and this light emitting signal line can simultaneously control the turn-on and turn-off of the fifth transistor T5 in the n-th unit row and the sixth transistor T6 in the (n−1)-th unit row. For another example, the fifth active layer 15n+1 of a pixel drive circuit in the n+1-th unit row is arranged in a circuit unit of the n-th unit row, so that the fifth active layer 15n+1 of the pixel drive circuit in the (n+1)-th unit row and the sixth active layer 16 of the pixel drive circuit in the n-th unit row may share one light emitting signal line, and this light emitting signal line can simultaneously control the turn-on and turn-off of the fifth transistor T5 in the (n+1)-th unit row and the sixth transistor T6 in the n-th unit row.

In an exemplary implementation, the eighth active layer 18 of the pixel drive circuit in a circuit unit of the current unit row may be located on a side of the seventh active layer 17 of the pixel drive circuit in a circuit unit of the previous unit row in the first direction X, so that the seventh active layer 17 and the eighth active layer 18 respectively in the two unit rows may share one scan signal line, and this scan signal line can simultaneously control the turn-on and turn-off of the seventh transistor T7 of the current unit row and the eighth transistor T8 of the next unit row. For example, the eighth active layer 18 of a pixel drive circuit in the n-th unit row is arranged in a circuit unit of the (n−1)-th unit row, so that the eighth active layer 18 of the pixel drive circuit in the n-th unit row and the seventh active layer 17n-1 of the pixel drive circuit in the (n−1)-th unit row may share one scan signal line, and this scan signal line can simultaneously control the turn-on and turn-off of the seventh transistor T7 of the (n−1)-th unit row and the eighth transistor T8 of the n-th unit row. For another example, the eighth active layer 18n+1 of a pixel drive circuit in the n+1-th unit row is arranged in a circuit unit of the n-th unit row, so that the eighth active layer 18n+1 of the pixel drive circuit in the (n+1)-th unit row and the seventh transistor T7 of the pixel drive circuit in the n-th unit row can share one scan signal line, and this scan signal line can simultaneously control the turn-on and turn-off of the seventh transistor T7 in the n-th unit row and the eighth transistor T8 in the (n+1)-th unit row.

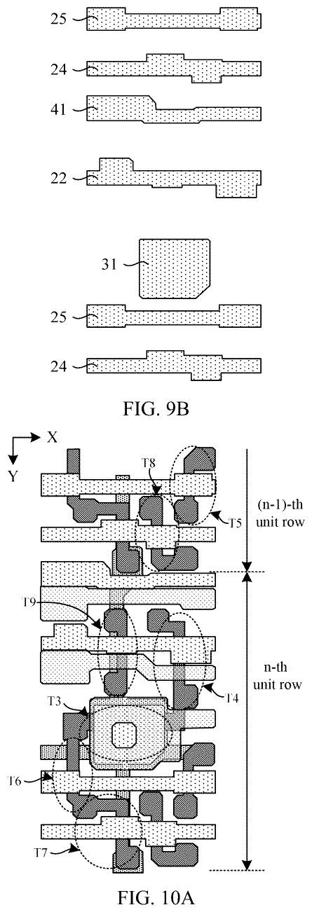

In an exemplary implementation, the first semiconductor layer may be made of polysilicon (p-Si), i.e., the third transistor T3 to the ninth transistor T9 are LTPS transistors. In an exemplary implementation, the patterning the first semiconductor thin film through the patterning process may include: forming an amorphous silicon (a-si) thin film on the first insulating thin film, dehydrogenating the amorphous silicon thin film, and crystallizing the dehydrogenated amorphous silicon thin film to form a polysilicon thin film; subsequently, patterning the poly silicon thin film to form the pattern of the first semiconductor layer.
(3) A pattern of a first conductive layer is formed. In an exemplary implementation, forming the pattern of the first conductive layer may include: depositing sequentially a second insulating thin film and a first conductive thin film on the substrate on which the aforementioned patterns are formed, and patterning the first conductive thin film through a patterning process to form a second insulating layer that covers the pattern of the first semiconductor layer and form the pattern of the first conductive layer arranged on the second insulating layer, as shown in FIG. 9A and FIG. 9B. FIG. 9B is a schematic plan view of the first conductive layer in FIG. 9A. In an exemplary implementation, the first conductive layer may be referred to as a first gate metal (GATE1) layer.

In an exemplary implementation, the pattern of the first conductive layer of each circuit unit may at least include: a second scan signal line 22, a fourth scan signal line 24, a light emitting signal line 25, a first initial signal line 41 and a first plate 31 of the storage capacitor.

In an exemplary implementation, the first plate 31 may be in a shape of a rectangle, and a chamfer may be provided at a corner of the rectangle. An orthographic projection of the first plate 31 on the substrate is at least partially overlapped with an orthographic projection of the third active layer of the third transistor T3 on the substrate. In an exemplary implementation, the first plate 31 may serve as one plate of the storage capacitor and a gate electrode of the third transistor T3 simultaneously.

In an exemplary implementation, an orthographic projection of the first plate 31 on the substrate overlaps at least partially with an orthographic projection of the shielding electrode 93 on the substrate.

In an exemplary implementation, main body portion of the second scan signal line 22 may be in a shape of a straight line or a polyline extending in the first direction X, the second scan signal line 22 may be located on a side of the first plate 31 in the opposite direction of the second direction Y, a region where the second scan signal line 22 overlaps with the fourth active layer may serve as the gate electrode of the fourth transistor T4, and a region where the second scan signal line 22 overlaps with the ninth active layer may serve as the gate electrode of the ninth transistor T9.

In an exemplary implementation, main body portion of the fourth scan signal line 24 may be in a shape of a straight line or a polyline extending in the first direction X, the fourth scan signal line 24 may be located on a side of the first plate 31 in the second direction Y, a region where the fourth scan signal line 24 of the current unit row overlaps with the seventh active layer of the pixel drive circuit in the current unit row may serve as the gate electrode of the seventh transistor T7 of the current unit row, and a region where the fourth scan signal line 24 of the current unit row overlaps with the eighth active layer of the pixel drive circuit in the next unit row may serve as the gate electrode of the eighth transistor T8 of the next unit row. For example, for the fourth scan signal line 24 of the (n−1)-th unit row, the region where it overlaps with the seventh active layer of the pixel drive circuit in the (n−1)-th unit row may serve as the gate electrode of the seventh transistor T7 in the (n−1)-th unit row, and the region where it overlaps with the eighth active layer of the pixel drive circuit in the n-th unit row may serve as the gate electrode of the eighth transistor T8 in the n-th unit row. For another example, for the fourth scan signal line 24 of the n-th unit row, a region where it overlaps with the seventh active layer of the pixel drive circuit in the n-th unit row may serve as the gate electrode of the seventh transistor T7 in the n-th unit row, and a region where it overlaps with the eighth active layer of the pixel drive circuit in the (n+1)-th unit row may serve as the gate electrode of the eighth transistor T8 in the (n+1)-th unit row.

In an exemplary implementation, main body portion of the light emitting signal line 25 may be in a shape of a straight line or a polyline extending in the first direction X, the light emitting signal line 25 may be located between the first plate 31 and the fourth scan signal line 24, a region where the light emitting signal line 25 of the current unit row overlaps with the sixth active layer of the pixel drive circuit in the current unit row may serve as the gate electrode of the sixth transistor T6 of the current unit row, and a region where the light emitting signal line 25 of the current unit row overlaps with the fifth active layer of the pixel drive circuit in the next unit row may serve as the gate electrode of the fifth transistor T5 of the next unit row. For example, for the light emitting signal line 25 of the (n−1)-th unit row, a region where it overlaps with the sixth active layer of the pixel drive circuit in the (n−1)-th unit row may serve as the gate electrode of the sixth transistor T6 in the (n−1)-th unit row, and a region where it overlaps with the fifth active layer of the pixel drive circuit in the n-th unit row may serve as the gate electrode of the fifth transistor T5 in the n-th unit row. For another example, for the light emitting signal line 25 of the n-th unit row, a region where it overlaps with the sixth active layer of the pixel drive circuit in the n-th unit row may serve as the gate electrode of the sixth transistor T6 in the n-th unit row, and a region where it overlaps with the fifth active layer of the pixel drive circuit in the (n+1)-th unit row may serve as the gate electrode of the fifth transistor T5 in the (n+1)-th unit row.

In an exemplary implementation, main body portion of the first initial signal line 41 may be in a shape of a straight line or a polyline extending in the first direction X, the first initial signal line 41 may be located on a side of the second scan signal line 22 away from the first plate 31, and the first initial signal line 41 is configured to be connected to the first region of the first active layer by a seventh connection electrode formed subsequently.

In an exemplary implementation, the second scan signal line 22, the fourth scan signal line 24, the light emitting signal line 25 and the first initial signal line 41 may be designed with non-equal widths, and the width is a dimension in the second direction Y, which can not only facilitate the layout of the pixel structure, but also reduce the parasitic capacitance between the signal lines, which is not limited here in the present disclosure.

In an exemplary implementation, the second scan signal line 22, the fourth scan signal line 24 and the light emitting signal line 25 may include a region overlapping with the first semiconductor layer and a region not overlapping with the first semiconductor layer, and a width of the signal line in the region overlapping with the first semiconductor layer may be greater than a width of the signal line in the region not overlapping with the first semiconductor layer.

In an exemplary implementation, a size of a region where the second scan signal line 22 overlaps with the fourth active layer in the second direction Y may be larger than a size of a region where the second scan signal line 22 overlaps with the ninth active layer in the second direction Y, so that a channel length of the fourth transistor T4 is larger than a channel length of the ninth transistor T9, and in the case where a difference between the channel widths of the fourth transistor T4 and the ninth transistor T9 is small, a channel width-length ratio of the ninth transistor T9 is larger than that of the fourth transistor T4.

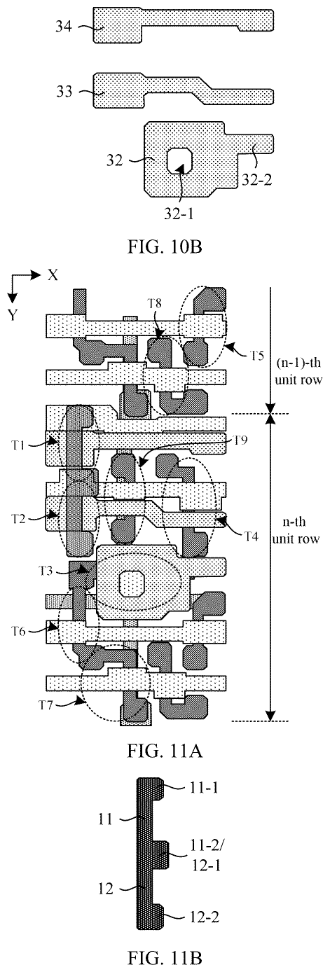

In an exemplary implementation, after the pattern of the first conductive layer is formed, the first conductive layer may be used as a shield to perform a conducting processing on the first semiconductor layer, the first semiconductor layer in a region shielded by the first conductive layer forms channel regions of the third transistor T3 to the ninth transistor T9, and the first semiconductor layer in a region not shielded by the first conductive layer is made to be conductive. That is, the first plate 31, and the first regions and the second regions of the third active layer 13 to the ninth active layer 19 are all made to be conductive.
(4) A pattern of a second conductive layer is formed. In an exemplary implementation, forming the pattern of the second conductive layer may include: depositing sequentially a third insulating thin film and a second conductive thin film on the substrate on which the aforementioned patterns are formed, and the second conductive thin film is patterned through a patterning process to form a third insulating layer that covers the first conductive layer, and the pattern of the second conductive layer arranged on the third insulating layer, as shown in FIG. 10A and FIG. 10B. FIG. 10B is a schematic plan diagram of the second conductive layer in FIG. 10A. In an exemplary implementation, the second conductive layer may be referred to as a second gate metal (GATE2) layer.

In an exemplary implementation, the pattern of the second conductive layer of each circuit unit at least includes: a second plate 32 of the storage capacitor, a first shielding line 33 and a second shielding line 34.

In an exemplary implementation, a profile of the second plate 32 may be in a shape of a rectangle, a chamfer may be provided at a corner of the rectangle, an orthographic projection of the second plate 32 on the substrate overlaps at least partially with an orthographic projection of the first plate 31 on the substrate, the second plate 32 may serve as the other plate of the storage capacitor, and the first plate 31 and the second plate 32 form the storage capacitor of the pixel drive circuit.

In an exemplary implementation, the second plate 32 is provided with an opening 32-1 which may be in a shape of a rectangle and may be located in a middle region of the second plate 32, so that the second plate 32 forms an annular structure. The opening 32-1 exposes the third insulating layer covering the first plate 31, and the orthographic projection of the first plate 31 on the substrate contains an orthographic projection of the opening 32-1 on the substrate. In an exemplary implementation, the opening 32-1 is configured to accommodate a fifteenth via formed subsequently, and the fifteenth via is located within the opening 32-1 and exposes the first plate 31, so that a first connection electrode formed subsequently is connected to the first plate 31 through this via.

In an exemplary implementation, a plate block 32-2 may be arranged on the second plate 32. The plate block 32-2 may be in a shape of a strip extending in the first direction X, a first terminal of the plate block 32-2 is connected to an edge on a side of the second plate 32 in the first direction X, and a second terminal of the plate block 32-2 extends in a direction away from the second plate 32.

In an exemplary implementation, main body portion of the first shielding line 33 may be in a shape of a straight line or a polyline extending in the first direction X, the first shielding line 33 may be located between the first plate 31 and the second scan signal line 22, and the first shielding line 33 is configured to serve as a shielding layer of the second transistor T2 to shield the channel region of the second transistor T2, ensuring the electrical performance of the second oxide transistor T2, and is also configured to serve as a bottom gate electrode of the second transistor T2.

In an exemplary implementation, main body portion of the second shielding line 34 may be in a shape of a straight line or a polyline extending in the first direction X, the second shielding line 34 may be located between the second scan signal line 22 and the first initial signal line 41, and the second shielding line 34 is configured to serve as a shielding layer of the first transistor T1 to shield the channel region of the first transistor T1, ensuring the electrical performance of the first oxide transistor T1, and is also configured to serve as a bottom gate electrode of the first transistor T1.

In an exemplary implementation, the first shielding line 33 and the second shielding line 34 may be designed with non-equal widths, which can not only facilitate the layout of the pixel structure, but also reduce the parasitic capacitance between the signal lines.
(5) A pattern of a second semiconductor layer is formed. In an exemplary implementation, forming the pattern of the second semiconductor layer may include: depositing a fourth insulating thin film and a second semiconductor thin film sequentially on the substrate on which the above-mentioned patterns are formed, patterning the second semiconductor thin film through a patterning process to form a fourth insulating layer that covers the substrate, and the pattern of the second semiconductor layer arranged on the fourth insulating layer, as shown in FIG. 11A and FIG. 11B. FIG. 11B is a schematic plan view of the second conductive layer in FIG. 11A.

In an exemplary implementation, a pattern of a second semiconductor layer of each circuit unit at least includes a first active layer 11 of the first transistor T1 and a second active layer 12 of the second transistor T2.

In an exemplary implementation, main body portions of the first active layer 11 and the second active layer 12 may be in a shape of a strip extending in the second direction Y, an orthographic projection of the first active layer 11 on the substrate overlaps at least partially with an orthographic projection of the second shielding line 34 on the substrate, and an orthographic projection of the second active layer 12 on the substrate overlaps at least partially with an orthographic projection of the first shielding line 33 on the substrate.

In an exemplary implementation, the first region 11-1 of the first active layer may be located on a side of the second shielding line 34 away from the second plate 32, the second region 12-2 of the second active layer may be located on a side of the first shielding line 33 close to the second plate 32, the second region 11-2 of the first active layer is connected to the first region 12-1 of the second active layer, and the second region 11-2 of the first active layer may serve as the first region 12-1 of the second active layer.

In an exemplary implementation, the first active layer 11 and the second active layer 12 may be connected to each other to form an integrated structure.

In an exemplary implementation, the second active layer 12 may be located on a side of the ninth active layer 19 in the opposite direction of the first direction X. Since the fourth active layer 14 is located on a side of the ninth active layer 19 in the first direction X, the ninth active layer 19 may be located between the second active layer 12 and the fourth active layer 14 in the first direction X, i.e., the channel region of the ninth transistor T9 is located between the channel region of the second transistor T2 and the channel region of the fourth transistor T4.

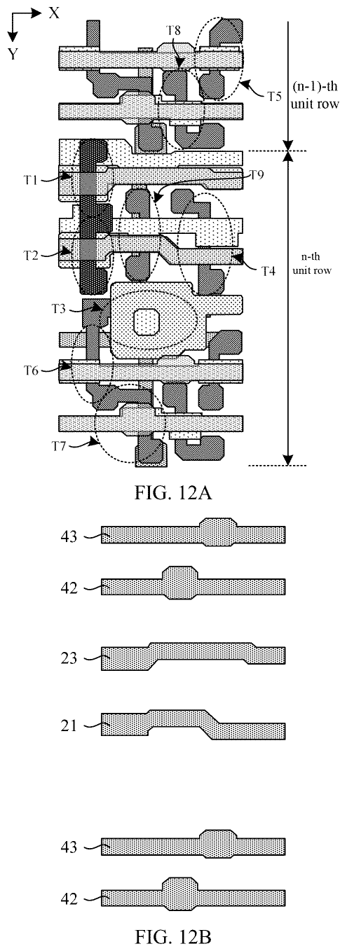

In an exemplary implementation, the second semiconductor layer may be made of an oxide, i.e., the eighth transistor T8 is an oxide transistor. In an exemplary implementation, the second semiconductor thin film may be made of Indium Gallium Zinc Oxide (IGZO), wherein electron mobility of the Indium Gallium Zinc Oxide (IGZO) is higher than that of amorphous silicon.
(6) A pattern of a third conductive layer is formed. In an exemplary implementation, forming the pattern of the third conductive layer may include: depositing a fifth insulating thin film and a third conductive thin film sequentially on the substrate on which the aforementioned patterns are formed, and patterning the third conductive thin film through a patterning process to form a fifth insulating layer covering the second semiconductor layer, and the pattern of the third conductive layer arranged on the fifth insulating layer, as shown in FIG. 12A and FIG. 12B. FIG. 12B is a schematic plan view of the third conductive layer in FIG. 12A. In an exemplary implementation, the second conductive layer may be referred to as a third gate metal (GATE3) layer.

In an exemplary implementation, the pattern of the third conductive layer of each circuit unit at least includes: a first scan signal line 21, a third scan signal line 23, a second initial signal line 42 and a third initial signal line 43.

In an exemplary implementation, main body portion of the first scan signal line 21 may be in a shape of a straight line or a polyline extending in the first direction X, the first scan signal line 21 may be located between the first plate 31 and the second scan signal line 22, and a region where the first scan signal line 21 overlaps with the second active layer may serve as the gate electrode of the second transistor T2.

In an exemplary implementation, an orthographic projection of the first scan signal line 21 on the substrate overlaps at least partially with the orthographic projection of the first shielding line 33 on the substrate, and the first scan signal line 21 and the first shielding line 33 may be connected to a same signal source, so that the first shielding line 33 may serve as the bottom gate electrode of the second transistor T2, and the first scan signal line 21 may serve as the top gate electrode of the second transistor T2, thereby forming the second transistor T2 of a top-bottom gate structure.

In an exemplary implementation, main body portion of the third scan signal line 23 may be in a shape of a straight line or a polyline extending in the first direction X, the third scan signal line 23 may be located between the second scan signal line 22 and the first initial signal line 41, and a region where the third scan signal line 23 overlaps with the first active layer may serve as the gate electrode of the first transistor T1.

In an exemplary implementation, an orthographic projection of the third scan signal line 23 on the substrate overlaps at least partially with the orthographic projection of the second shielding line 34 on the substrate, and the third scan signal line 23 and the second shielding line 34 can be connected to a same signal source, so that the second shielding line 34 may serve as the bottom gate electrode of the first transistor T1, and the third scan signal line 23 may serve as the top gate electrode of the first transistor T1, thereby forming the first transistor T1 of a top-bottom gate structure.

In an exemplary implementation, main body portion of the second initial signal line 42 may be in a shape of a straight line or a polyline extending in the first direction X, the second initial signal line 42 may be located on a side of the second light emitting signal line 32 away from the second plate 32, and the second initial signal line 42 of the current unit row is configured to be connected to the first region of the seventh active layer of the pixel drive circuit in a circuit unit in the current unit row through an eighth connection electrode formed subsequently.

In an exemplary implementation, an orthographic projection of the second initial signal line 42 on the substrate overlaps at least partially with the orthographic projection of the fourth scan signal line 24 on the substrate, so that the second initial signal line 42 having a constant potential can effectively block the influence of the voltage jump of the fourth scan signal line 24 on the pixel drive circuit.

In an exemplary implementation, main body portion of the third initial signal line 43 may be in a shape of a straight line or a polyline extending in the first direction X, the third initial signal line 43 may be located between the second plate 32 and the second initial signal line 42, and the third initial signal line 43 of the current unit row is configured to be connected to the first region of the eighth active layer of the pixel drive circuit in a circuit unit of the next unit row through a ninth connection electrode formed subsequently. For example, the third initial signal line 43 in the (n−1)-th unit row is configured to be connected to the first region of the eighth active layer of the pixel drive circuit in a circuit unit in the n-th unit row through a ninth connection electrode formed subsequently. For another example, the third initial signal line 43 in the n-th unit row is configured to be connected to the first region of the eighth active layer of the pixel drive circuit in a circuit unit in the (n+1)-th unit row through a ninth connection electrode formed subsequently.

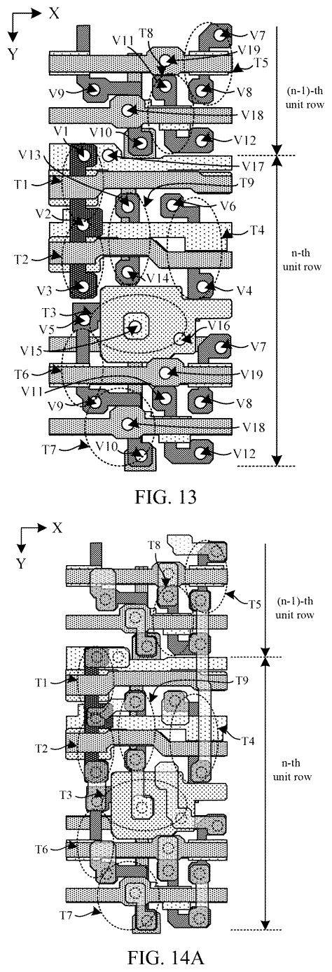

In an exemplary implementation, an orthographic projection of the third initial signal line 43 on the substrate overlaps at least partially with an orthographic projection of the light emitting signal line 25 on the substrate, so that the third initial signal line 43 having a constant potential can effectively block the influence of the voltage jump of the light emitting signal line 25 on the pixel drive circuit.
(7) A pattern of a sixth insulating layer is formed. In an exemplary implementation, forming the pattern of the sixth insulating layer may include: depositing a sixth insulating thin film on the substrate on which the aforementioned patterns are formed, patterning the fifth insulating thin film using a patterning process to form a sixth insulating layer covering the third conductive layer, wherein a plurality of vias are arranged on the sixth insulating layer, as shown in FIG. 13.

In an exemplary implementation, a plurality of vias of each circuit unit at least includes: a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17, an eighteenth via V18 and a nineteenth via V19.

In an exemplary implementation, an orthographic projection of the first via V1 on the substrate is within a range of an orthographic projection of the first region of the first active layer on the substrate, the sixth insulating layer and the fifth insulating layer within the first via V1 are etched away to expose a surface of the first region of the first active layer, and the first via V1 is configured such that a seventh connection electrode formed subsequently is connected to the first region of the first active layer through the first via V1.

In an exemplary implementation, an orthographic projection of the second via V2 on the substrate is within a range of an orthographic projection of the second region of the first active layer (also the first region of the second active layer) on the substrate, the sixth insulating layer and the fifth insulating layer within the second via V2 are etched away to expose a surface of the second region of the first active layer (also the first region of the second active layer), and the second via V2 is configured such that a tenth connection electrode formed subsequently is connected to the second region of the first active layer (also the first region of the second active layer) through the second via V2.

In an exemplary implementation, an orthographic projection of the third via V3 on the substrate is within a range of an orthographic projection of the second region of the second active layer on the substrate, the sixth insulating layer and the fifth insulating layer within the third via V3 are etched away to expose a surface of the second region of the second active layer, and the third via V3 is configured such that a second connection electrode subsequently formed is connected to the second region of the second active layer through the third via V3.

In an exemplary implementation, an orthographic projection of the fourth via V4 on the substrate is within a range of an orthographic projection of the first region of the third active layer (also the second region of the fourth active layer) on the substrate, the sixth insulating layer, the fifth insulating layer, the fourth insulating layer, the third insulating layer and the second insulating layer within the fourth via V4 are etched away to expose a surface of the first region of the third active layer (also the second region of the fourth active layer), and the fourth via V4 is configured such that a fifth connection electrode formed subsequently is connected to the first region of the third active layer (also the second region of the fourth active layer) through the fourth via V4.

In an exemplary implementation, an orthographic projection of the fifth via V5 on the substrate is within an orthographic projection of the second region of the third active layer (also the first region of the sixth active layer) on the substrate, the sixth insulating layer, the fifth insulating layer, the fourth insulating layer, the third insulating layer and the second insulating layer within the fifth via V5 are etched away to expose the surface of the second region of the third active layer (also the first region of the sixth active layer), and the fifth via V5 is configured such that a subsequently formed second connection electrode is connected to the second region of the third active layer (also the first region of the sixth active layer) through the fifth via V5.

In an exemplary implementation, an orthographic projection of the sixth via V6 on the substrate is within a range of an orthographic projection of a first region of the fourth active layer on the substrate, the sixth insulating layer, the fifth insulating layer, the fourth insulating layer, the third insulating layer and the second insulating layer within the sixth via V6 are etched away to expose a surface of the first region of the fourth active layer, and the sixth via V6 is configured such that a third connection electrode to be formed subsequently is connected to the first region of the fourth active layer through the sixth via V6.

In an exemplary implementation, an orthographic projection of the seventh via V7 on the substrate is within a range of an orthographic projection of a first region of the fifth active layer on the substrate, the sixth insulating layer, the fifth insulating layer, the fourth insulating layer, the third insulating layer and the second insulating layer within the seventh via V7 are etched away to expose a surface of the first region of the fifth active layer, and the seventh via V7 is configured such that the fourth connection electrode to be formed subsequently is connected to the first region of the fifth active layer through the seventh via V7.

In an exemplary implementation, the pixel drive circuits of two adjacent circuit units in the first direction X may be substantially mirror symmetrical with respect to a column reference line, the two adjacent circuit units may share one seventh via V7, and the column reference line may be a straight line located between the two adjacent circuit units and extending in the second direction Y.

In an exemplary implementation, an orthographic projection of the eighth via V8 on the substrate is within a range of an orthographic projection of the second region of the fifth active layer on the substrate, the sixth insulating layer, the fifth insulating layer, the fourth insulating layer, the third insulating layer and the second insulating layer within the eighth via V8 are etched away to expose a surface of the second region of the fifth active layer, and the eighth via V8 is configured such that a fifth connection electrode formed subsequently is connected to the second region of the fifth active layer through the eighth via V8.

In an exemplary implementation, an orthographic projection of the ninth via V9 on the substrate is within an orthographic projection of the second region of the sixth active layer (also the second region of the seventh active layer) on the substrate, the sixth insulating layer, the fifth insulating layer, the fourth insulating layer, the third insulating layer and the second insulating layer within the ninth via V9 are etched away to expose the surface of the second region of the sixth active layer (also the second region of the seventh active layer), and the ninth via V9 is configured such that a subsequently formed sixth connection electrode is connected to the second region of the sixth active layer (also the second region of the seventh active layer) through the ninth via V9.

In an exemplary implementation, an orthographic projection of the tenth via V10 on the substrate is within a range of an orthographic projection of a first region of the seventh active layer on the substrate, the sixth insulating layer, the fifth insulating layer, the fourth insulating layer, the third insulating layer and the second insulating layer within the tenth via V10 are etched away to expose a surface of the first region of the seventh active layer, and the tenth via V10 is configured such that an eighth connection electrode to be formed subsequently is connected to the first region of the seventh active layer through the tenth via V10.

In an exemplary implementation, an orthographic projection of an eleventh via V11 on the substrate is within an orthographic projection of the first region of the eighth active layer on the substrate, the sixth insulating layer, the fifth insulating layer, the fourth insulating layer, the third insulating layer and the second insulating layer within the eleventh via V11 are etched away to expose the surface of the first region of the eighth active layer, and the eleventh via V11 is configured such that a subsequently formed ninth connection electrode is connected to the first region of the eighth active layer through the eleventh via V11.

In an exemplary implementation, an orthographic projection of the twelfth via V12 on the substrate is within a range of an orthographic projection of a second region of the eighth active layer on the substrate, the sixth insulating layer, the fifth insulating layer, the fourth insulating layer, the third insulating layer and the second insulating layer within the twelfth via V12 are etched away to expose a surface of the second region of the eighth active layer, and the twelfth via V12 is configured such that a fifth connection electrode to be formed subsequently is connected to the second region of the eighth active layer through the twelfth via V12.

In an exemplary implementation, an orthographic projection of the thirteenth via V13 on the substrate is within a range of an orthographic projection of the first region of the ninth active layer on the substrate, the sixth insulating layer, the fifth insulating layer, the fourth insulating layer, the third insulating layer and the second insulating layer within the thirteenth via V13 are etched away to expose a surface of the first region of the ninth active layer, and the thirteenth via V13 is configured such that a tenth connection electrode formed subsequently is connected to the first region of the ninth active layer through the thirteenth via V13.

In an exemplary implementation, an orthographic projection of the fourteenth via V14 on the substrate is within a range of an orthographic projection of the second region of the ninth active layer on the substrate, the sixth insulating layer, the fifth insulating layer, the fourth insulating layer, the third insulating layer and the second insulating layer within the fourteenth via V14 are etched away to expose a surface of the second region of the ninth active layer, and the fourteenth via V14 is configured such that a first connection electrode formed subsequently is connected to the second region of the ninth active layer through the fourteenth via V14.

In an exemplary implementation, an orthographic projection of the fifteenth via V15 on the substrate is within a range of an orthographic projection of the opening 32-1 on the substrate, the sixth insulating layer, the fifth insulating layer, the fourth insulating layer and the third insulating layer within the fifteenth via V15 are etched away to expose a surface of the first plate 31, and the fifteenth via V15 is configured such that a first connection electrode formed subsequently is connected to the first plate 31 through the fifteenth via V15.

In an exemplary implementation, an orthographic projection of the sixteenth via V16 on the substrate is within a range of an orthographic projection of the second plate 32 on the substrate, the sixth insulating layer, the fifth insulating layer and the fourth insulating layer within the sixteenth via V16 are etched away to expose a surface of the second plate 32, and the sixteenth via V16 is configured such that a fourth connection electrode formed subsequently is connected to the second plate 32 through the sixteenth via V16.

In an exemplary implementation, an orthographic projection of the seventeenth via V17 on the substrate is within a range of an orthographic projection of the first initial signal line 41 on the substrate, the sixth insulating layer, the fifth insulating layer, the fourth insulating layer and the third insulating layer within the seventeenth via V17 are etched away to expose a surface of the first initial signal line 41, and the seventeenth via V17 is configured such that a seventh connection electrode formed subsequently is connected to the first initial signal line 41 through the seventeenth via V17.

In an exemplary implementation, an orthographic projection of the eighteenth via V18 on the substrate is within a range of an orthographic projection of the second initial signal line 42 on the substrate, the sixth insulating layer within the eighteenth via V18 is etched away to expose a surface of the second initial signal line 42, and the eighteenth via V18 is configured such that an eighth connection electrode formed subsequently is connected to the second initial signal line 42 through the eighteenth via V18.

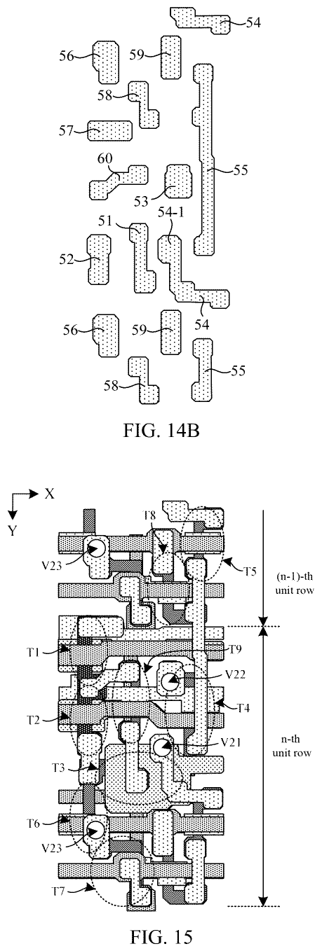

In an exemplary implementation, an orthographic projection of the nineteenth via V19 on the substrate is within a range of an orthographic projection of the third initial signal line 43 on the substrate, the sixth insulating layer within the nineteenth via V19 is etched away to expose a surface of the third initial signal line 43, and the nineteenth via V19 is configured such that a ninth connection electrode formed subsequently is connected to the third initial signal line 43 through the nineteenth via V19.
(8) A pattern of a fourth conductive layer is formed. In an exemplary implementation, forming the pattern of the fourth conductive layer may include: depositing a fourth conductive thin film on the substrate on which the aforementioned patterns are formed, and patterning the fourth conductive thin film through a patterning process to form the fourth conductive layer arranged on the sixth insulating layer, as shown in FIG. 14A and FIG. 14B. FIG. 14B is a schematic plan view of the fourth conductive layer in FIG. 14A. In an exemplary implementation, the fourth conductive layer may be referred to as a first source drain metal (SD1) layer.

In an exemplary implementation, a fourth conductive layer of each circuit unit at least includes: a first connection electrode 51, a second connection electrode 52, a third connection electrode 53, a fourth connection electrode 54, a fifth connection electrode 55, a sixth connection electrode 56, a seventh connection electrode 57, an eighth connection electrode 58, a ninth connection electrode 59 and a tenth connection electrode 60.

In an exemplary implementation, main body portion of the first connection electrode 51 may be in a shape of a strip extending in the second direction Y, a first terminal of the first connection electrode 51 is connected to the second region of the ninth active layer through the fourteenth via V14, and a second terminal of the first connection electrode 51 extends in the second direction Y to be connected to the first plate 31 through the fifteenth via V15. In an exemplary implementation, since the first plate 31 simultaneously serves as the gate electrode of the third transistor T3, the first connection electrode 51 enables the gate electrode of the third transistor T3, the second electrode of the ninth transistor T9 and the first plate 31 to have a same potential and form the first node N1 of the pixel drive circuit.

In an exemplary implementation, main body portion of the second connection electrode 52 may be in a shape of a strip extending in the second direction Y, a first terminal of the second connection electrode 52 is connected to the second region of the second active layer through the third via V3, and a second terminal of the second connection electrode 52 extends in the second direction Y to be connected to the second region of the third active layer (also the first region of the sixth active layer) through the fifth via V5. In an exemplary implementation, the second connection electrode 52 enables the second electrode of the second transistor T2, the second electrode of the third transistor T3, and the first electrode of the sixth transistor T6 to have a same potential and form the third node N3 of the pixel drive circuit.

In an exemplary implementation, the third connection electrode 53 may be in a shape of a block (e.g., a rectangle), the third connection electrode 53 is connected to the first region of the fourth active layer through the sixth via V6, and the third connection electrode 53 is configured to be connected to a data signal line formed subsequently.

In an exemplary implementation, the fourth connection electrode 54 may be in a shape of L, a first terminal of the fourth connection electrode 54 is connected to the first region of the fifth active layer through the seventh via V7, and a second terminal of the fourth connection electrode 54 is connected to the second plate 32 through the sixteenth via V16, thus achieving that the first electrode of the fifth transistor T5 and the second plate 32 of the storage capacitor in the circuit unit have a same potential.

In an exemplary implementation, the pixel drive circuits of two adjacent circuit units in the first direction X may be substantially mirror symmetrical with respect to a column reference line, and the fourth connection electrodes 54 of the two adjacent circuit units may be connected to each other to form an integrated structure, and are connected to the first regions of the fifth active layers of the two circuit units through a shared seventh via V7.

In an exemplary implementation, a power supply connection block 54-1 is arranged on the fourth connection electrode 54, the power supply connection block 54-1 is arranged on a side of the second terminal of the fourth connection electrode 54 away from the first terminal, and the power supply connection block 54-1 is configured to be connected to a first power supply line formed subsequently.

In an exemplary implementation, since the fifth active layer of a pixel drive circuit in the current unit row is arranged in a circuit unit of the previous unit row, a first terminal of a fourth connection electrode 54 in the current unit row is connected to a first region of a fifth active layer of a pixel drive circuit in a next unit row, and a second terminal of the fourth connection electrode 54 is connected to a second plate 32 of the pixel drive circuit in the current unit row. For example, for a fourth connection electrode 54 of a pixel drive circuit in the n-th unit row, its first terminal is connected to a first region of a fifth active layer of a pixel drive circuit in the (n+1)-th unit row, and its second terminal is connected to a second plate 32 of the pixel drive circuit in the n-th unit row. For another example, for a fourth connection electrode 54 in the (n−1)-th unit row, its first terminal is connected to a first region of a fifth active layer of a pixel drive circuit in the n-th unit row, and its second terminal is connected to a second plate 32 of a pixel drive circuit in the (n−1)-th unit row.

In an exemplary implementation, main body portion of the fifth connection electrode 55 may be in a shape of a strip extending in the second direction Y, a first terminal of the fifth connection electrode 55 is connected to the second region of the fifth active layer through the eighth via V8, a second terminal of the fifth connection electrode 55 extends in the second direction Y to be connected to the first region of the third active layer (also the second region of the fourth active layer) through the fourth via V4, and a region between the first terminal and the second terminal of the fifth connection electrode 55 is connected to the second region of the eighth active layer through the twelfth via V12. In an exemplary implementation, the fifth connection electrode 55 enables the first electrode of the third transistor T3, the second electrode of the fourth transistor T4, the second electrode of the fifth transistor T5, and the second electrode of the eighth transistor T8 to have the same potential, and form the second node N2 of the pixel drive circuit. In an exemplary implementation, the fifth connection electrode 55 may serve as a second node electrode in the present disclosure.

In an exemplary implementation, since a fifth active layer of a pixel drive circuit in the current unit row is arranged in a circuit unit of a previous unit row, a fifth connection electrode 55 in the current unit row spans two circuit units. A via through which the fifth connection electrode 55 is connected to the second region of the fifth active layer and the second region of the eighth active layer is located in the circuit unit of the previous unit row, and a via through which the fifth connection electrode 55 is connected to the first region of the third active layer (also the second region of the fourth active layer) is located in a circuit unit of the current unit row. For example, for a fifth connection electrode 55 of a pixel drive circuit in the n-th unit row, a via through which it is connected to the second region of the fifth active layer and the second region of the eighth active layer of the pixel drive circuit in the n-th unit row is located in a circuit unit in the (n−1)-th unit row, and a via through which it is connected to the first region of the third active layer (also the second region of the fourth active layer) of the pixel drive circuit in the n-th unit row is located in a circuit unit of the n-th unit row. For another example, for a fifth connection electrode 55 in the (n+1)-th unit row, a via through which it is connected to the second region of the fifth active layer and the second region of the eighth active layer of a pixel drive circuit in the (n+1)-th unit row is located in a circuit unit of the n-th unit row, and a via through which it is connected to the first region of the third active layer (also the second region of the fourth active layer) of a pixel drive circuit in the (n+1)-th unit row is located in a circuit unit of the (n+1)-th unit row.

In an exemplary implementation, an orthographic projection of the fifth connection electrode 55 (the second node N2 of the pixel drive circuit) on the substrate overlaps at least partially with orthographic projections of the first initial signal line 41 and the second initial signal line 42 on the substrate, so that the first initial signal line 41 and the second initial signal line 42 having a constant potential can effectively stabilize the potential of the second node N2.

In an exemplary implementation, the orthographic projection of the fifth connection electrode 55 on the substrate overlaps at least partially with orthographic projections of the first scan signal line 21, the second scan signal line 22, the third scan signal line 23 and the fourth scan signal line 24 on the substrate. Since a power supply voltage output from the first power supply line is provided to the second node N2 in the sixth stage of the drive timing of the pixel drive circuit, the influence of various scan lines on the second node N2 may be reset, and the light emission stability of the light emission stage can be improved.

In an exemplary implementation, the sixth connection electrode 56 may be in a shape of a block (such as a rectangle), and the sixth connection electrode 56 is connected to the second region of the sixth active layer (also the second region of the seventh active layer) through the ninth via V9. In an exemplary implementation, the sixth connection electrode 56 is configured to be connected to an anode connection electrode formed subsequently, and form the fourth node N4 of the pixel drive circuit.

In an exemplary implementation, main body portion of the seventh connection electrode 57 may be in a shape of a strip extending in the first direction X, a first terminal of the seventh connection electrode 57 is connected to the first region of the first active layer through the first via V1, and a second terminal of the seventh connection electrode 57 is connected to the first initial signal line 41 through the seventeenth via V17. In an exemplary implementation, the seventh connection electrode 57 achieves the connection of the first initial signal line 41 to the first electrode of the first transistor T1, and the first initial signal line 41 may write the transmitted first initial signal to the first electrode of the first transistor T1.

In an exemplary implementation, main body portion of the eighth connection electrode 58 may be in a shape of a strip extending in the second direction Y, a first terminal of the eighth connection electrode 58 is connected to the first region of the seventh active layer through the tenth via V10, and a second terminal of the eighth connection electrode 58 is connected to the second initial signal line 42 through the eighteenth via V18. In an exemplary implementation, the eighth connection electrode 58 achieves the connection of the second initial signal line 42 to the first electrode of the seventh transistor T7, and the second initial signal line 42 may write the transmitted second initial signal to the first electrode of the seventh transistor T7.

In an exemplary implementation, main body portion of the ninth connection electrode 59 may be in a shape of a strip extending in the second direction Y, a first terminal of the ninth connection electrode 59 is connected to the first region of the eighth active layer through the eleventh via V11, and a second terminal of the ninth connection electrode 59 is connected to the third initial signal line 43 through the nineteenth via V19. In an exemplary implementation, the ninth connection electrode 59 achieves the connection of the third initial signal line 43 to the first electrode of the eighth transistor T8, and the third initial signal line 43 may write the transmitted third initial signal to the first electrode of the eighth transistor T8.

In an exemplary implementation, since an eighth active layer of a pixel drive circuit in the current unit row is arranged in a circuit unit of a previous unit row, a first terminal of a ninth connection electrode 59 in the current unit row is connected to a first region of an eighth active layer of a pixel drive circuit in a next unit row, and a second terminal of the ninth connection electrode 59 is connected to a third initial signal line 43 in the current unit row. For example, for a ninth connection electrode 59 in the (n−1)-th unit row, its first terminal is connected to a first region of an eighth active layer of a pixel drive circuit in the n-th unit row, and its second terminal is connected to a third initial signal line 43 in the (n−1)-th unit row. For another example, for a ninth connection electrode 59 of a pixel drive circuit in the n-th unit row, its first terminal is connected to a first region of an eighth active layer of a pixel drive circuit in the (n+1)-th unit row, and its second terminal is connected to a third initial signal line 43 in the n-th unit row.

In an exemplary implementation, main body portion of the tenth connection electrode 60 may be in a shape of a strip extending in the first direction X, a first terminal of the tenth connection electrode 60 is connected to the second region of the first active layer (also the first region of the second active layer) through the second via V2, and a second terminal of the tenth connection electrode 60 is connected to the first region of the ninth active layer through the thirteenth via V13. In an exemplary implementation, the tenth connection electrode 60 achieves the connection of the second electrode of the first transistor T1, the first electrode of the second transistor T2, and the first electrode of the ninth transistor T9, and form the fifth node N5 of the pixel drive circuit.
(9) A pattern of a first planarization layer is formed. In an exemplary implementation, forming the pattern of the first planarization layer may include: coating a first planarization thin film on the substrate on which the aforementioned patterns are formed, patterning the first planarization thin film using a patterning process to form a first planarization layer covering the pattern of the fourth conductive layer, wherein the first planarization layer is provided with a plurality of vias, as shown in FIG. 15.

In an exemplary implementation, a plurality of vias in each circuit unit at least includes a twenty-first via V21, a twenty-second via V22, and a twenty-third via V23.

In an exemplary implementation, an orthographic projection of the twenty-first via V21 on the substrate is within a range of an orthographic projection of the power supply connection block 54-1 of the fourth connection electrode 54 on the substrate, the first planarization layer within the twenty-first via V21 is etched away to expose a surface of the power supply connection block 54-1, and the twenty-first via V21 is configured such that a first power supply line formed subsequently is connected to the power supply connection block 54-1 through the twenty-first via V21.

In an exemplary implementation, an orthographic projection of the twenty-second via V22 on the substrate is within a range of an orthographic projection of the third connection electrode 53 on the substrate, the first planarization layer within the twenty-second via V22 is etched away to expose a surface of the third connection electrode 53, and the twenty-second via V22 is configured such that a data signal line formed subsequently is connected to the third connection electrode 53 through the twenty-second via V22.

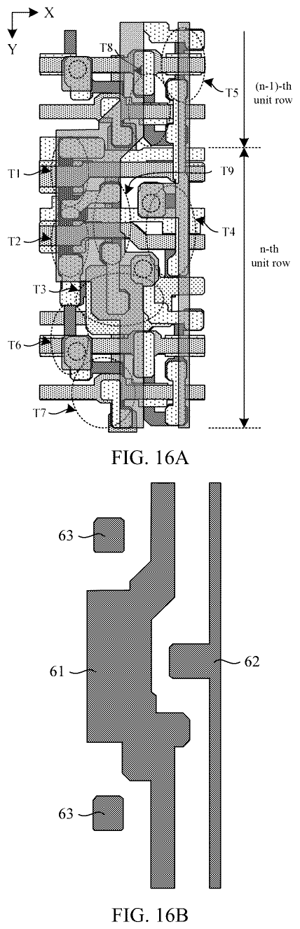

In an exemplary implementation, an orthographic projection of the twenty-third via V23 on the substrate is within a range of an orthographic projection of the sixth connection electrode 56 on the substrate, the first planarization layer in the twenty-third via V23 is etched away to expose a surface of the sixth connection electrode 56, and the twenty-third via V23 is configured such that an anode connection electrode to be formed subsequently is connected to the sixth connection electrode 56 through the twenty-third via V23.
(10) A pattern of a fifth conductive layer is formed. In an exemplary implementation, forming the pattern of the fifth conductive layer may include: depositing a fifth conductive thin film on the substrate on which the above-mentioned patterns are formed, and patterning the fifth conductive thin film using a patterning process to form the fifth conductive layer arranged on the first planarization layer, as shown in FIG. 16A and FIG. 16B. FIG. 16B is a schematic plan view of the fifth conductive layer in FIG. 16A. In an exemplary implementation, the fifth conductive layer may be referred to as a second source-drain metal (SD2) layer.

In an exemplary implementation, a fifth conductive layer of each circuit unit includes at least a first power supply line 61, a data signal line 62 and an anode connection electrode 63.

In an exemplary implementation, main body portion of the first power supply line 61 may be in a shape of a straight line or a polyline extending in the second direction Y, and the first power supply line 61 is connected to the power supply connection block 54-1 through the twenty-first via V21. Since the power supply connection block 54-1 is connected to the fourth connection electrode 54, and the fourth connection electrode 54 is connected to the first electrode of the fifth transistor T5 and the second plate 32 of the storage capacitor, thereby the first power supply line 61 writes the first power supply signal to the fifth transistor T5 and the second plate 32 of the storage capacitor.

In an exemplary implementation, the first power supply line 61 may be of a polyline with unequal widths, which may not only facilitate a layout of a pixel structure, but also reduce a parasitic capacitance between the first power supply line and a data signal line.

In an exemplary implementation, an orthographic projection of the first power supply line 61 on the substrate overlaps at least partially with an orthographic projection of the first active layer on the substrate, and the orthographic projection of the first power supply line 61 on the substrate overlaps at least partially with an orthographic projection of the second active layer on the substrate, so that the first power supply line 61 may shield the first active layer and the second active layer, which can prevent the light emitted from the light emitting device and the reflected light of the film layers from irradiating the first oxide transistor T1 and the second oxide transistor T2, and can avoid characteristic drifting of the oxide transistors from due to illumination, thus improving electrical performance of the oxide transistors.

In an exemplary implementation, an orthographic projection of the first power supply line 61 on the substrate at least partially overlaps an orthographic projection of the first connection electrode 51 on the substrate, and the first power supply line 61 with a constant potential can effectively block from the influence of the data voltage jump and other signals on the first node N1 in the pixel drive circuit, avoid the influence of the data voltage jump and other signals on the potential of the first node N1, and improve the driving performance of the pixel drive circuit.

In an exemplary implementation, the orthographic projection of the first power supply line 61 on the substrate overlaps at least partially with orthographic projections of the second connection electrode 52 and the tenth connection electrode 60 on the substrate, and the first power supply line 61 having a constant potential can effectively block the influence of the data voltage jump and other signals on various nodes in the pixel drive circuit, thereby avoiding the influence of the data voltage jump and other signals on the potentials of the nodes, and improving the driving performance of the pixel drive circuit.

In an exemplary implementation, main body portion of the data signal line 62 may be in a shape of a straight line or a polyline extending in the second direction Y, and the data signal line 62 is connected to the third connection electrode 53 through the twenty-second via V22. Since the third connection electrode 53 is connected to the first region of the fourth active layer through a via, connection between the data signal line 62 and the first electrode of the fourth transistor T4 is achieved, and the data signal line 62 can write a data signal to the first electrode of the fourth transistor T4.

In an exemplary implementation, the anode connection electrode 63 may be in a shape of a block (e.g., a rectangle), the anode connection electrode 63 is connected to the sixth connection electrode 56 through the twenty-third via V23, and the anode connection electrode 63 is configured to be connected to an anode formed subsequently. Since the sixth connection electrode 56 is connected to the second region of the sixth active layer and a second region of the seventh active layer through a via, connection between the anode formed subsequently and the second electrode of the sixth transistor T6 as well as the second electrode of the seventh transistor T7 may be achieved, and the pixel drive circuit may drive the light emitting device to emit light.

The subsequent process may include forming a second planarization layer covering the pattern of the fifth conductive layer. The second planarization layer is provided with an anode via. The anode via exposes the anode connection electrode and is configured such that an anode formed subsequently is connected to the anode connection electrode through the anode via.

So far, a drive circuit layer has been manufactured on the substrate. In a plane parallel to the display substrate, the drive circuit layer may include a plurality of circuit units, and each circuit unit may include a pixel drive circuit, and a first scan signal line, a second scan signal line, a third scan signal line, a fourth scan signal line, a light emitting signal line, a first initial signal line, a second initial signal line, a third initial signal line, a first power supply line and a data signal line which are connected to the pixel drive circuit. In a plane perpendicular to the display substrate, the drive circuit layer may include a shielding layer, a first insulating layer, a first semiconductor layer, a second insulating layer, a first conductive layer, a third insulating layer, a second conductive layer, a fourth insulating layer, a second semiconductor layer, a fifth insulating layer, a third conductive layer, a sixth insulating layer, a fourth conductive layer, a first planarization layer, a fifth conductive layer and a second planarization layer arranged sequentially on the substrate. The shielding layer may at least include a shielding electrode; the first semiconductor layer may at least include active layers of the third transistor to the ninth transistor; the first conductive layer may at least include a second scan signal line, a fourth scan signal line, a light emitting signal line, a first initial signal line and a first plate of the storage capacitor; the second conductive layer may at least include a first shielding line, a second shielding line and a second plate of the storage capacitor; the second semiconductor layer may at least include active layers of the first transistor and the second transistor; the third conductive layer may at least include a first scan signal line, a third scan signal line, a second initial signal line and a third initial signal line; the fourth conductive layer may at least include a plurality of connection electrodes; and the fifth conductive layer may at least include a first power supply line, a data signal line and an anode connection electrode.

In an exemplary implementation, the substrate may be a flexible substrate, or a rigid substrate. The rigid substrate may include, but is not limited to, one or more of glass and quartz. The flexible substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation, the flexible substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the substrate. The first inorganic material layer and the second inorganic material layer may also be referred to as barrier layers, and a material of the semiconductor layer may be amorphous silicon (a-si).

In an exemplary implementation, the first conductive layer, the second conductive layer, the third conductive layer, the fourth conductive layer, and the fifth conductive layer may be made of a metal material, such as any one or more of Argentum (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo. The first insulating layer, the second insulating layer, the third insulating layer, the fourth insulating layer, the fifth insulating layer, and the sixth insulating layer may be made of any one or more of Silicon Oxide (SiOx), Silicon Nitride (SiNx), and Silicon OxyNitride (SiON), and may be a single layer, multiple layers, or a composite layer. The first planarization layer and the second planarization layer may be made of an organic material, such as resin.

In an exemplary implementation, after the drive circuit layer has been prepared, a light emitting structure layer may be prepared on the drive circuit layer first, and then an encapsulation structure layer may be prepared on the light emitting structure layer, which will not be described further here.

A pixel drive circuit of a display substrate adopts an 8T1C structure, in which the first transistor T1 and the second transistor T2 are oxide transistors, the third transistor T3 to the eighth transistor T8 are low-temperature polysilicon transistors, and the first node N1 of the pixel drive circuit is connected to the second electrode of the first transistor T1, the first electrode of the second transistor T2, the gate electrode of the third transistor T3, and the first terminal of the storage capacitor C. During a product reliability test, the display substrate has the defect of transverse stripes. Studies show that the occurrence of transverse stripes is due to characteristic shift of the second oxide transistor T2. Circuit bias and high temperature for long time in the product reliability test will cause characteristic shift of the second oxide transistor T2, especially shift of the threshold voltage Vth. The pixel drive circuit is very sensitive to the characteristic change of the second transistor T2, especially the change of the threshold voltage Vth. The shift of the threshold voltage Vth of the second transistor T2 will cause the potential of the gate electrode (the first node N1) of the drive transistor to fluctuate, and a small fluctuation will cause a large change in the light emission current, thereby causing the occurrence of transverse stripes. Under low brightness and low gray scale, the phenomenon of transverse stripes is more serious.

In the display substrate provided by an embodiment of the present disclosure, by arranging the ninth transistor T9 of low-temperature polysilicon between the oxide transistor and the gate electrode of the drive transistor, the potential fluctuation of the gate electrode of the drive transistor caused by the characteristic change of the second transistor T2 can be effectively avoided, and the defect of transverse stripes can be reduced or eliminated. The pixel drive circuit of the display substrate of the present disclosure adopts a 9T1C structure, in which a polysilicon ninth transistor T9 is added on the basis of the 8T1C structure, and the ninth transistor T9 is arranged among the gate electrode of the drive transistor, and the second electrode of the first transistor T1 and the first electrode of the second transistor T2 to isolate the gate electrode of the drive transistor from the first oxide transistor T1 and the second oxide transistor T2. Since the characteristics of the ninth polysilicon transistor T9 are relatively stable and the ninth transistor T9 is turned off before the second transistor T2 is turned off in the fourth stage, the influence of the characteristic change of the second transistor T2 on the potential of the gate electrode of the drive transistor is effectively eliminated, and the change in the light emission current is avoided, thereby effectively reducing or eliminating the defect of transverse stripes.

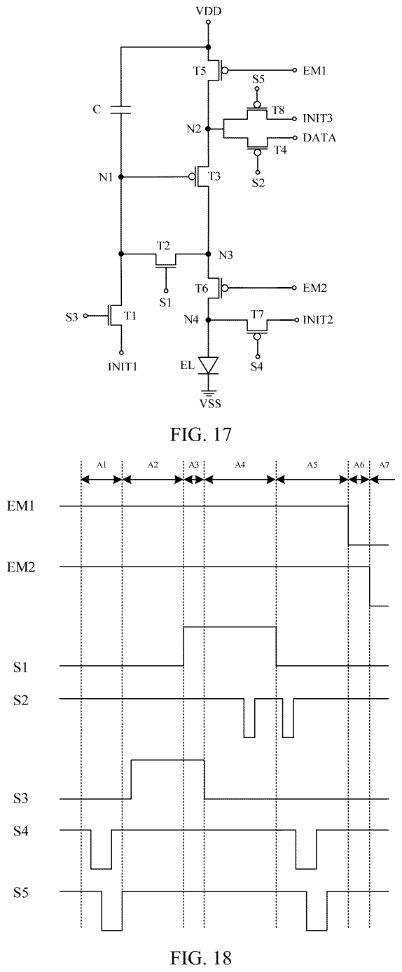

FIG. 17 is an equivalent circuit diagram of another pixel drive circuit according to an exemplary embodiment of the present disclosure. As shown in FIG. 17, the pixel drive circuit is of an 8T1C structure, and may include eight transistors (a first transistor T1 to an eighth transistor T8) and one storage capacitor C. Each pixel drive circuit is connected to 12 signal lines (a first scan signal line S1, a second scan signal line S2, a third scan signal line S3, a fourth scan signal line S4, a fifth scan signal line S5, a first light emitting signal line EM1, a second light emitting signal line EM2, a first initial signal line INIT1, a second initial signal line INIT2, a third initial signal line INIT3, a data signal line DATA and a first power supply line VDD).

In an exemplary implementation, the connection structure of the first transistor T1 to the eighth transistor T8 and the storage capacitor C in the pixel drive circuit of the present embodiment is substantially the same as that shown in FIG. 4, except that the pixel drive circuit is not provided with a ninth transistor, so that the first node N1 is connected to the second electrode of the first transistor T1, the first electrode of the second transistor T2, the gate electrode of the third transistor T3 and the first terminal of the storage capacitor C, respectively, that is, the second electrode of the first transistor T1 is connected to the first node N1, and the first electrode of the second transistor T2 is connected to the first node N1.

As shown in FIG. 17, in this exemplary embodiment, the first transistor T1 and the second transistor T2 in the pixel drive circuit may be oxide transistors (N-type transistors), and the third transistor T3 to the eighth transistor T8 may be low temperature polysilicon transistors (P-type transistors).

FIG. 18 is a drive timing diagram of the pixel drive circuit shown in FIG. 17. As shown in FIG. 18, in an exemplary implementation, the working process of the pixel drive circuit is substantially the same as that in FIG. 5A, except that in the second stage A2, the second scan signal line S2 is a high-level signal, and the first transistor T1 is turned on, so that the signal of the first initial signal line INIT1 is provided to the first node N1 to initialize (reset) the first node N1; in the fifth stage A5, before the seventh transistor T7 and the eighth transistor T8 are turned on, the signal of the second scan signal line S2 is a low-level signal for a short period of time, and the fourth transistor T4 is turned on again, so that the data voltage of the next unit row resets the second node N2 and the third node N3.

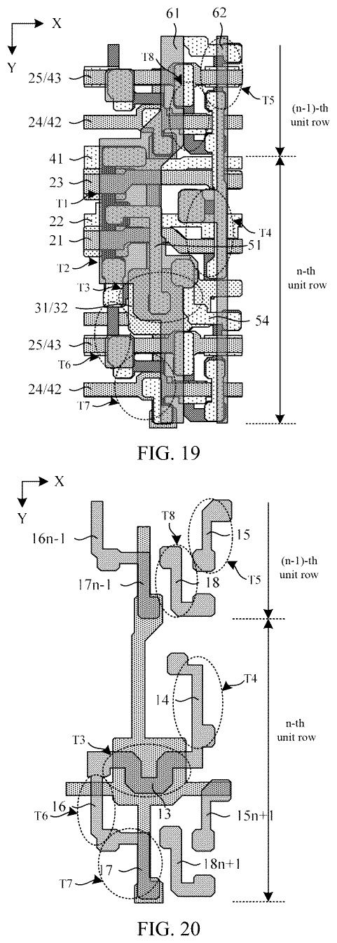

FIG. 19 is a schematic diagram of a planar structure of another display substrate according to an exemplary embodiment of the present disclosure. In an exemplary implementation, the structure of the display substrate of the present embodiment is substantially the same as that shown in FIG. 6, except that the pixel drive circuit is of an 8T1C structure.

In an exemplary implementation, the pixel drive circuit includes a storage capacitor and a plurality of transistors, the storage capacitor may include a first plate and a second plate which are stacked, and the plurality of transistors may include a first transistor T1 as a first initialization transistor, a second transistor T2 as a compensation transistor, a third transistor T3 as a drive transistor, a fourth transistor T4 as a data writing transistor, a fifth transistor T5 as a first light emitting control transistor, a sixth transistor T6 as a second light emitting control transistor, a seventh transistor T7 as a second initialization transistor, and an eighth transistor T8 as a third initialization transistor. The first transistor T1 and the second transistor T2 are oxide transistors, and the third transistor T3 to the ninth transistor T9 are low-temperature polysilicon transistors.

In an exemplary implementation, the connection structure of the first transistor T1 to the eighth transistor T8 is substantially the same as that in the foregoing embodiment, except that the second electrode of the first transistor T1 and the first electrode of the second transistor T2 are connected to the first plate 31 of the storage capacitor through the first connection electrode 51.

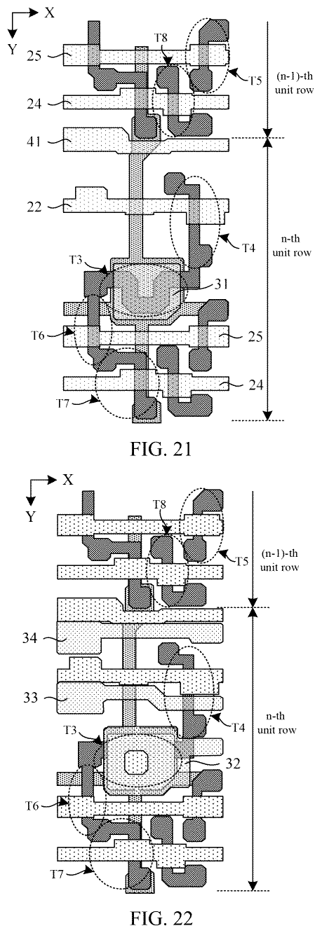

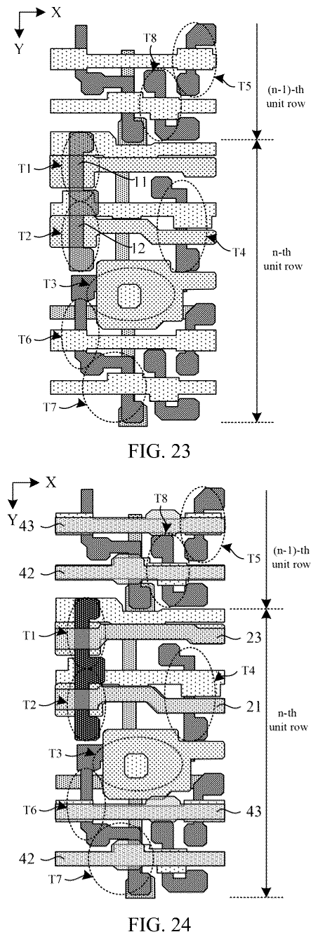

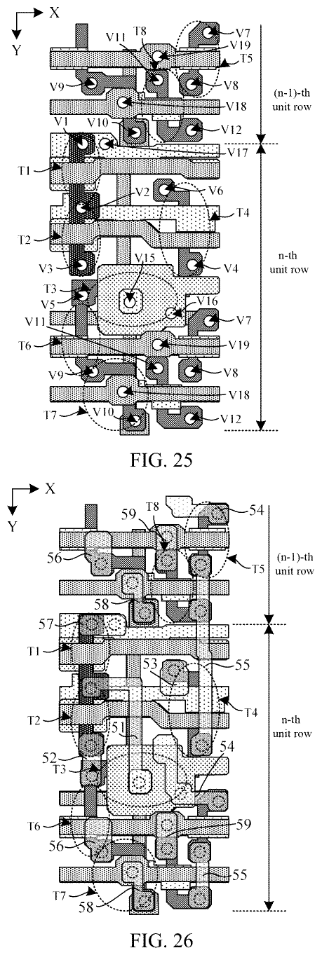

In an exemplary implementation, taking one circuit unit as an example, the manufacturing process of the display substrate in this embodiment may include the following operations.
(11) A pattern of a shielding layer is formed. In an exemplary implementation, the process of forming the shielding layer and the structure of the shielding layer are substantially the same as those in the foregoing embodiment.
(12) A pattern of a first semiconductor layer is formed. In an exemplary implementation, the process of forming the first semiconductor layer and the structure of the first semiconductor layer are substantially the same as those in the foregoing embodiment, except that the first semiconductor layer may at least include the third active layer 13 of the third transistor T3 to the eighth active layer 18 of the eighth transistor T8, and the first semiconductor layer is not provided with a ninth active layer, as shown in FIG. 20.
(13) A pattern of a first conductive layer is formed. In an exemplary implementation, the process of forming the first conductive layer and the structure of the first conductive layer are substantially the same as those in the foregoing embodiment, as shown in FIG. 21.
(14) A pattern of a second conductive layer is formed. In an exemplary implementation, the process of forming the second conductive layer and the structure of the second conductive layer are substantially the same as those in the foregoing embodiment, as shown in FIG. 22.
(15) A pattern of a second semiconductor layer is formed. In an exemplary implementation, the process of forming the second semiconductor layer and the structure of the second semiconductor layer are substantially the same as those in the foregoing embodiment, as shown in FIG. 23.
(16) A pattern of a third conductive layer is formed. In an exemplary implementation, the process of forming the third conductive layer and the structure of the third conductive layer are substantially the same as those in the foregoing embodiment, as shown in FIG. 24.
(17) A pattern of a sixth insulating layer is formed. In an exemplary implementation, the process of forming the sixth insulating layer and the structure of the plurality of vias are substantially the same as those in the foregoing embodiment, except that a plurality of vias of each circuit unit do not include the thirteenth via V13 and the fourteenth via V14, and the second via V2 is configured such that the first connection electrode formed subsequently is connected to the second region of the first active layer (also the first region of the second active layer) through the second via V2, as shown in FIG. 25.
(18) A pattern of a fourth conductive layer is formed. In an exemplary implementation, the process of forming the fourth conductive layer and the structure of the fourth conductive layer are substantially the same as those in the foregoing embodiment, except that the fourth conductive layer is not provided with a tenth connection electrode, the first connection electrode 51 is in a shape of L, the first terminal of the first connection electrode 51 is connected to the second region of the first active layer (also the first region of the second active layer) through the second via V2, and the second terminal of the first connection electrode 51 is connected to the first plate 31 through the fifteenth via V15, as shown in FIG. 26.

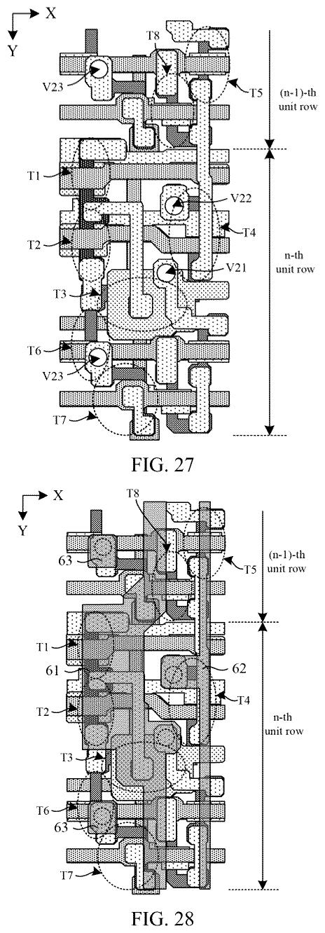

In an exemplary implementation, the first connection electrode 51 enables the second electrode of the first transistor T1, the first electrode of the second transistor T2, the gate electrode of the third transistor T3, the second electrode of the ninth transistor T9, and the first plate 31 to have a same potential, and form the first node N1 of the pixel drive circuit.
(19) A pattern of a first planarization layer is formed. In an exemplary implementation, the process of forming the first planarization layer and the structure of the plurality of vias are substantially the same as those in the foregoing embodiment, as shown in FIG. 27.
(20) A pattern of a fifth conductive layer is formed. In an exemplary implementation, the process of forming the fifth conductive layer and the structure of the fifth conductive layer are substantially the same as those in the foregoing embodiment, as shown in FIG. 28.

The subsequent process may include forming a second planarization layer covering the pattern of the fifth conductive layer; wherein the second planarization layer is provided with an anode via, the anode via exposes the anode connection electrode and is configured such that an anode formed subsequently is connected to the anode connection electrode through the anode via.

So far, a drive circuit layer has been manufactured on the substrate. In a plane parallel to the display substrate, the drive circuit layer may include a plurality of circuit units, and each circuit unit may include a pixel drive circuit, and a first scan signal line, a second scan signal line, a third scan signal line, a fourth scan signal line, a light emitting signal line, a first initial signal line, a second initial signal line, a third initial signal line, a first power supply line and a data signal line which are connected to the pixel drive circuit. In a plane perpendicular to the display substrate, the drive circuit layer may include a shielding layer, a first insulating layer, a first semiconductor layer, a second insulating layer, a first conductive layer, a third insulating layer, a second conductive layer, a fourth insulating layer, a second semiconductor layer, a fifth insulating layer, a third conductive layer, a sixth insulating layer, a fourth conductive layer, a first planarization layer, a fifth conductive layer, and a second planarization layer that are arranged sequentially on the substrate. The shielding layer may at least include a shielding electrode; the first semiconductor layer may at least include active layers of the third transistor to the eighth transistor; the first conductive layer may at least include a second scan signal line, a fourth scan signal line, a light emitting signal line, a first initial signal line and a first plate of the storage capacitor; the second conductive layer may at least include a first shielding line, a second shielding line and a second plate of the storage capacitor; the second semiconductor layer may at least include active layers of the first transistor and the second transistor; the third conductive layer may at least include a first scan signal line, a third scan signal line, a second initial signal line and a third initial signal line; the fourth conductive layer may at least include a plurality of connection electrodes; and the fifth conductive layer may at least include a first power supply line, a data signal line and an anode connection electrode.

In an exemplary implementation, after the drive circuit layer has been prepared, a light emitting structure layer may be prepared on the drive circuit layer first, and then an encapsulation structure layer may be prepared on the light emitting structure layer, which will not be described further here.

In a display substrate, a pixel drive circuit of each circuit unit is connected to five scan signal lines (the first scan signal line to the fifth scan signal line) and two light emitting signal lines (the first light emitting signal line and the second light emitting signal line). The many signal lines not only increase the occupied area, but also increase the complexity of the structure of the pixel drive circuit. Therefore, it is difficult to reduce the size of the circuit unit and it is also difficult to improve the resolution (Pixels Per Inch, abbreviated as PPI) of a display apparatus. In addition, a large number of scan signal lines and light emitting signal lines increase the number of corresponding gate drive circuits in the bezel region, which increases the gate drive circuits and the occupied area, and is not conducive to achieving a narrow bezel.

In the display substrate provided by an embodiment of the present disclosure, by means of signal borrowing of two adjacent unit rows, the fifth transistor T5 of the current unit row is controlled by the light emitting signal line of the previous unit row, and the eighth transistor T8 of the current unit row is controlled by the fourth scan signal line of the previous unit row, which can effectively reduce the size of the circuit unit and effectively improve the resolution of the display apparatus.

In the display substrate of the present disclosure, the sixth transistor T6 of the pixel drive circuit in the current unit row is arranged in the circuit unit of the current unit row, the sixth transistor T6 is connected to the light emitting signal line of the current unit row, the fifth transistor T5 of the pixel drive circuit in the current unit row is arranged in the circuit unit of the previous unit row, and the fifth transistor T5 is connected to the light emitting signal line of the previous unit row, thus realizing that the fifth transistor T5 of the current unit row borrows the control signal of the sixth transistor T6 of the previous unit row. Compared with an existing structure in which a first light emitting signal line controlling the fifth transistor T5 and a second light emitting signal line controlling the sixth transistor T6 are arranged in each unit row, in the present disclosure, by staggered arrangement of transistors in neighboring unit rows and signal borrowing, only one light emitting signal line is arranged in the unit row, which not only reduces the number of signal lines and reduces the occupied area, but also reduces the complexity of the structure of the pixel drive circuit, thereby effectively reducing the size of the circuit unit, and effectively improving the resolution of the display apparatus.

In the present disclosure, the fifth transistor and the sixth transistor are separated in control, the fifth transistor T5 of the current unit row is connected to the light emitting signal line of the previous unit row, the sixth transistor T6 is connected to the light emitting signal line of the previous unit row, and the light emitting signal lines of two unit rows jointly adjust the duty cycle of the pulse width modulation (PWM), so that ultra-high frequency pulse width modulation with higher accuracy, duty cycle compensation of the light emitting signal, low grayscale compensation and improvement of image sticking can be achieved.

In the display substrate of the present disclosure, the seventh transistor T7 of the pixel drive circuit in the current unit row is arranged in the circuit unit of the current unit row, the seventh transistor T7 is connected to the fourth scan signal line of the current unit row, the eighth transistor T8 of the pixel drive circuit in the current unit row is arranged in the circuit unit of the previous unit row, and the eighth transistor T8 is connected to the fourth scan signal line of the previous unit row, thus realizing that the eighth transistor T8 of the current unit row borrows the control signal of the seventh transistor T7 of the previous unit row. Compared with an existing structure in which a fourth scan signal line controlling the seventh transistor T7 and a fifth scan signal line controlling the eighth transistor T8 are arranged in each unit row, in the present disclosure, by staggered arrangement of transistors in neighboring unit rows and signal borrowing, only one fourth scan signal line is arranged in the unit row, which not only reduces the number of signal lines and reduces the occupied area, but also reduces the complexity of the structure of the pixel drive circuit, thereby effectively reducing the size of the circuit unit, and effectively improving the resolution of the display apparatus.

In the present disclosure, by reducing the number of light emitting signal lines and scan signal lines in the unit row, the space utilization rate is optimized, and the layout is more reasonable, which can ensure the distances between the nodes and the distances between various nodes and signal lines in the interior of the pixel drive circuit, and can effectively avoid crosstalk, thereby effectively improving the display quality of the display apparatus, effectively improving the yield of the product, and reducing the production cost.

In the present disclosure, by reducing the number of light emitting signal lines and scan signal lines in the unit row, the number of corresponding gate drive circuits in the bezel region can be reduced exponentially, which effectively reduces the occupied area of the gate drive circuit, is conducive to realizing a narrow bezel, and improves product advantages.

In the present disclosure, the orthographic projection of the second initial signal line on the substrate overlaps at least partially with the orthographic projection of the fourth scan signal line on the substrate, and the orthographic projection of the third initial signal line on the substrate overlaps at least partially with the orthographic projection of the light emitting signal line on the substrate, so that the initial signal line having a constant potential can effectively block the influence of a voltage jump of the scan signal line or the light emitting signal line on the pixel drive circuit, thereby improving the driving performance of the pixel drive circuit.

In the present disclosure, by arranging the first power supply line to cover the first connection electrode, the influence of data voltage jump and other signals on the first node in the pixel drive circuit can be effectively blocked, thus avoiding the influence of data voltage jump and other signals on the potential of the first node, and effectively avoiding the deterioration of crosstalk. In the present disclosure, by arranging the first power supply line to cover the first active layer and the second active layer, light emitted by the light emitting device and light reflected by the film layers can be effectively blocked from irradiating oxide transistors, and characteristic drifting of the oxide transistors due to illumination can be avoided, thus improving electrical performance of the oxide transistors. The manufacturing process in the present disclosure may be compatible well with an existing manufacturing process, is simple in process implementation, is easy to implement, and has a high production efficiency, a low production cost, and a high yield.

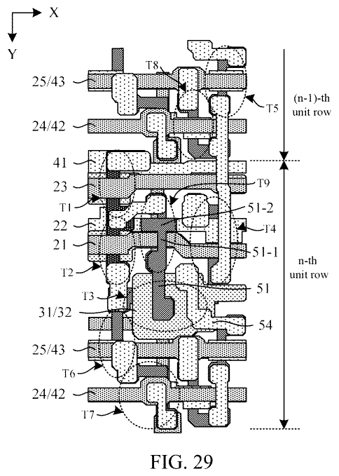

FIG. 29 is a schematic diagram of a planar structure of yet another display substrate according to an exemplary embodiment of the present disclosure. In an exemplary implementation, the structure of the display substrate of the present embodiment is substantially the same as that shown in FIG. 6, except that the first connection electrode 51 is also provided with a first auxiliary electrode 51-1 and a second auxiliary electrode 51-2.

In an exemplary implementation, main body portion of the first connection electrode 51 may be in a shape of a strip extending in the second direction Y, a first terminal of the first connection electrode 51 is connected to the second region of the ninth active layer through the fourteenth via V14, and a second terminal of the first connection electrode 51 extends in the second direction Y to be connected to the first plate 31 through the fifteenth via V15. In an exemplary implementation, since the first plate 31 simultaneously serves as the gate electrode of the third transistor T3, the first connection electrode 51 enables the gate electrode of the third transistor T3, the second electrode of the ninth transistor T9 and the first plate 31 to have a same potential, and form the first node N1 of the pixel drive circuit.

In an exemplary implementation, the first auxiliary electrode 51-1 may be in a shape of a strip extending in the second direction Y, a first terminal of the first auxiliary electrode 51-1 is connected to the first terminal of the first connection electrode 51, and a second terminal of the first auxiliary electrode 51-1 extends in a direction away from the first connection electrode 51 to be connected to the second auxiliary electrode 51-2. An orthographic projection of the first auxiliary electrode 51-1 on the substrate overlaps at least partially with the orthographic projection of the first scan signal line 21 on the substrate. The second auxiliary electrode 51-2 may be in a shape of a strip extending in the first direction X, and an orthographic projection of the second auxiliary electrode 51-2 on the substrate overlaps at least partially with the orthographic projection of the second scan signal line 22 on the substrate.

In an exemplary implementation, the second scan signal line 22 controls turn-on and turn-off of the fourth transistor T4, and the first connection electrode 51 serves as the first node N1 of the pixel drive circuit. In the present disclosure, the first node N1 is arranged to overlap with the first scan signal line 21 and the second scan signal line 22, which not only facilitates the display of a low grayscale picture, but also can balance parasitic capacitance between the first node N1 and the second scan signal line 22. The second transistor T2 is an N-type transistor, the fourth transistor T4 is a P-type transistor, and the turn-on signals of the first scan signal line 21 controlling the second transistor T2 and the second scan signal line 22 controlling the fourth transistor T4 are opposite to each other. Therefore, the structure of the first auxiliary electrode 51-1 and the second auxiliary electrode 51-2 in this embodiment can balance parasitic capacitance between the first node N1 and the second scan signal line 22.

In an exemplary implementation, there is an overlapping area between the orthographic projection of the first scan signal line 21 on the substrate and the orthographic projection of the ninth active layer on the substrate, and a width of the overlapping area in the ninth active layer may be greater than a width of other portions to adjust the capacitance between the first semiconductor layer and the first scan signal line 21. Since the first semiconductor layer in the lower layer is widened, it is not affected by the flatness of the first scan signal line 21 above, which improves the risk of line breakage.

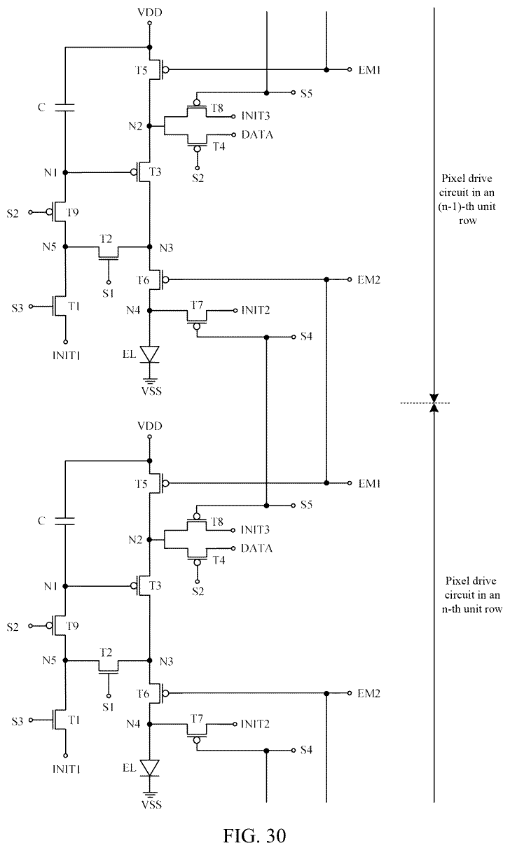

FIG. 30 is an equivalent circuit diagram of a still yet another pixel drive circuit according to an exemplary embodiment of the present disclosure, illustrating the pixel drive circuits of the (n−1)-th unit row and the n-th unit row, wherein the structure of the pixel drive circuits of the (n−1)-th unit row and the n-th unit row is substantially the same as those shown in FIG. 4.

As shown in FIG. 30, the second light emitting signal line EM2 of the (n−1-)th unit row and the first light emitting signal line EM1 of the n-th unit row are connected to each other, i.e., the second light emitting signal line EM2 of the (n−1)-th unit row and the first light emitting signal line EM1 of the n-th unit row are the same light emitting signal line, and the sixth transistor T6 of the (n−1)-th unit row and the fifth transistor T5 of the n-th unit row share this light emitting signal line. The fourth scan signal line S4 of the (n−1)-th unit row and the fifth scan signal line S5 of the n-th unit row are connected to each other, i.e., the fourth scan signal line S4 of the (n−1)-th unit row and the fifth scan signal line S5 of the n-th unit row are the same scan signal line, and the seventh transistor T7 of the (n−1)-th unit row and the eighth transistor T8 of the n-th unit row share this scan signal line.

In some possible implementations, the fourth scan signal line S4 and the fifth scan signal line S5 of each unit row may not employ cascaded signals, and employ a same control signal, and the fourth scan signal line S4 and the fifth scan signal line S5 of each unit row employ a same control signal, which is not limited here in the present disclosure.

In some possible implementations, the first scan signal line S1 and the third scan signal line S3 of each unit row may be provided by different gate drive circuits, or may employ cascaded signals, which is not limited here in the present disclosure.

The aforementioned structure shown in the present disclosure and the preparation process thereof are merely exemplary description. In an exemplary implementation, corresponding structures may be changed and patterning processes may be added or reduced according to actual needs, which is not limited here in the present disclosure.

In an exemplary implementation, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), which is not limited here in the present disclosure.

The present disclosure also provides a method for driving a display substrate, to drive the display substrate according to the aforementioned embodiments. In an exemplary implementation, the display substrate may include a plurality of circuit units constituting a plurality of unit rows and a plurality of unit columns, at least one circuit unit at least includes a pixel drive circuit and at least one control signal line, the pixel drive circuit at least includes a drive transistor, a first control transistor and a second control transistor, and the first control transistor and the second control transistor are connected to the drive transistor, respectively. In an exemplary implementation, the method for driving the display substrate may at least include a data writing stage and a light emitting stage. In the light emitting stage, in at least one pixel drive circuit of at least one unit row, turn-on and turn-off of the first control transistor are controlled by the control signal line in the previous unit row, and turn-on and turn-off of the second control transistor are controlled by the control signal line in the current unit row.

In an exemplary implementation, the pixel drive circuit further includes a first initialization transistor, a compensation transistor and an isolation transistor, a first electrode of the first initialization transistor is connected to a first initial signal line, a second electrode of the first initialization transistor and a first electrode of the compensation transistor are connected to a first electrode of the isolation transistor, a second electrode of the isolation transistor is connected to a gate electrode of the drive transistor, and a second electrode of the compensation transistor is connected to a second electrode of the drive transistor. The method for driving the display substrate further includes: turning on the isolation transistor at least twice prior to the data writing stage.

In an exemplary implementation, the method for driving the display substrate further includes a node reset stage between the data writing stage and the light emitting stage, and in the node reset stage, a first electrode and the second electrode of the drive transistor are reset.

The present disclosure also provides a preparation method for a display substrate, to prepare the display substrate according to the foregoing embodiments. In an exemplary implementation, the display substrate includes a plurality of circuit units constituting a plurality of unit rows and a plurality of unit columns. The preparation method may include: forming a pixel drive circuit and at least one control signal line in at least one circuit unit, wherein the pixel drive circuit at least includes a drive transistor, a first control transistor and a second control transistor, the first control transistor and the second control transistor are connected to the drive transistor, respectively; and in at least one pixel drive circuit of at least one unit row, the first control transistor is connected to the control signal line in a previous unit row, and the second control transistor is connected to the control signal line in the current unit row.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present invention.

Although implementations disclosed in the present disclosure are as above, it should be noted that the above implementations are exemplary only rather than restrictive. Therefore, the present disclosure is not limited to what is specifically shown and described herein. Various modifications, substitutions or omissions may be made in forms and details of implementation modes without departing from the scope of the present disclosure.

1. A display substrate, comprising a plurality of circuit units constituting a plurality of unit rows and a plurality of unit columns, wherein at least one circuit unit at least comprises a pixel drive circuit, and at least one control signal line configured to provide a control signal to the pixel drive circuit; in at least one circuit unit, the pixel drive circuit at least comprises a drive transistor, a first control transistor and a second control transistor, the first control transistor and the second control transistor are connected to the drive transistor, respectively; and in at least one pixel drive circuit of at least one unit row, the first control transistor is connected to a control signal line in a previous unit row, and the second control transistor is connected to a control signal line in the current unit row.

2. The display substrate according to claim 1, wherein the control signal line comprises a light emitting signal line, the first control transistor comprises a first light emitting control transistor, the second control transistor comprises a second light emitting control transistor, a first electrode of the first light emitting control transistor is connected to a first power supply line, a second electrode of the first light emitting control transistor is connected to a first electrode of the drive transistor, and a first electrode of the second light emitting control transistor is connected to a second electrode of the drive transistor; in at least one pixel drive circuit of at least one unit row, a gate electrode of the first control transistor is connected to a light emitting signal line in a previous unit row, and a gate electrode of the second control transistor is connected to a light emitting signal line in the current unit row.

3. The display substrate according to claim 2, wherein in at least one pixel drive circuit, the first light emitting control transistor and the second light emitting control transistor connected to a same drive transistor are respectively arranged on two sides of the drive transistor in a unit column direction.

4. The display substrate according to claim 2, wherein the first light emitting control transistor at least comprises a first light emitting control active layer, and the second light emitting control transistor at least comprises a second light emitting control active layer; and in at least one pixel drive circuit of at least one unit row, the first light emitting control active layer is arranged in a circuit unit of a previous unit row, and the second light emitting control active layer is arranged in a circuit unit of the current unit row.

5. The display substrate according to claim 4, wherein in at least one pixel drive circuit of at least one unit row, the first light emitting control active layer is arranged on a side of a second light emitting control active layer of a pixel drive circuit in a previous unit row in a unit row direction.

6. The display substrate according to claim 4, wherein the pixel drive circuit further comprises a storage capacitor and a power supply connection electrode, the storage capacitor comprises a first plate and a second plate, an orthographic projection of the first plate on a plane of the display substrate overlaps at least partially with an orthographic projection of the second plate on the plane of the display substrate; in at least one pixel drive circuit of at least one unit row, a first terminal of the power supply connection electrode is connected to a first region of the first light emitting control active layer of the pixel drive circuit in a next unit row, and a second terminal of the power supply connection electrode is connected to the second plate of the pixel drive circuit in the current unit row.

7. The display substrate according to claim 1, wherein the control signal line comprises a scan signal line, the first control transistor comprises a third initialization transistor, the second control transistor comprises a second initialization transistor, a first electrode of the second initialization transistor is connected to a second initial signal line, a second electrode of the second initialization transistor is connected to a second electrode of the drive transistor through a second light emitting control transistor, a first electrode of the third initialization transistor is connected to a third initial signal line, and a second electrode of the third initialization transistor is connected to a first electrode of the drive transistor; and in at least one pixel drive circuit of at least one unit row, a gate electrode of the third initialization transistor is connected to a scan signal line in a previous unit row, and a gate electrode of the second initialization transistor is connected to a scan signal line in the current unit row.

8. The display substrate according to claim 7, wherein in at least one pixel drive circuit, the second initialization transistor and the third initialization transistor connected to a same drive transistor are respectively arranged on two sides of the drive transistor in a unit column direction.

9. The display substrate according to claim 7, wherein the second initialization transistor at least comprises a second initialization active layer, and the third initialization transistor at least comprises a third initialization active layer; and in at least one pixel drive circuit of at least one unit row, the third initialization active layer is arranged in a circuit unit of a previous unit row, and the second initialization active layer is arranged in a circuit unit of the current unit row.

10. The display substrate according to claim 9, wherein in at least one pixel drive circuit of at least one unit row, the third initialization active layer is arranged on a side of a second initialization active layer of a pixel drive circuit in a previous unit row in a unit row direction.

11. The display substrate according to claim 9, wherein in at least one pixel drive circuit of at least one unit row, a first region of the second initialization active layer is connected to the second initial signal line in the current unit row, and a first region of the third initialization active layer is connected to a third initial signal line in a previous unit row.

12. The display substrate according to claim 1, wherein the pixel drive circuit further comprises a first initialization transistor, a compensation transistor and an isolation transistor, a first electrode of the first initialization transistor is connected to a first initial signal line, a second electrode of the first initialization transistor and a first electrode of the compensation transistor are connected to a first electrode of the isolation transistor, a second electrode of the isolation transistor is connected to a gate electrode of the drive transistor, and a second electrode of the compensation transistor is connected to a second electrode of the drive transistor.

13. The display substrate according to claim 12, wherein the pixel drive circuit further comprises a data writing transistor, a first electrode of the data writing transistor is connected to a data signal line, and a second electrode of the data writing transistor is connected to the first electrode of the drive transistor; and a channel region of the isolation transistor is located between a channel region of the compensation transistor and a channel region of the data writing transistor, and a channel width-length ratio of the isolation transistor is greater than a channel width-length ratio of the data writing transistor.

14. The display substrate according to claim 12, wherein the first control transistor comprises a first light emitting control transistor and a third initialization transistor, a first electrode of the first light emitting control transistor is connected to a first power supply line, a first electrode of the third initialization transistor is connected to a third initial signal line, and a second electrode of the first light emitting control transistor and a second electrode of the third initialization transistor are connected to the first electrode of the drive transistor; and the pixel drive circuit further comprises a second node electrode connected to the first electrode of the drive transistor, the second electrode of the first light emitting control transistor and the second electrode of the third initialization transistor, respectively, and an orthographic projection of the second node electrode on the plane of the display substrate overlaps at least partially with an orthographic projection of the first initial signal line on the plane of the display substrate.

15. The display substrate according to claim 1, wherein the pixel drive circuit further comprises a first initialization transistor and a compensation transistor, a first electrode of the first initialization transistor is connected to a first initial signal line, a second electrode of the first initialization transistor and a first electrode of the compensation transistor are connected to the gate electrode of the drive transistor, and a second electrode of the compensation transistor is connected to the second electrode of the drive transistor.

16. A display apparatus, comprising the display substrate according to claim 1.

17. A method for driving a display substrate, wherein the display substrate comprises a plurality of circuit units constituting a plurality of unit rows and a plurality of unit columns, at least one circuit unit at least comprises a pixel drive circuit and at least one control signal line, the pixel drive circuit at least comprises a drive transistor, a first control transistor and a second control transistor, the first control transistor and the second control transistor are connected to the drive transistor respectively; the method at least comprises a data writing stage and a light emitting stage, in the light emitting stage, in at least one pixel drive circuit of at least one unit row, turn-on and turn-off of the first control transistor are controlled by a control signal line in a previous unit row, and turn-on and turn-off of the second control transistor are controlled by a control signal line in the current unit row.

18. The method according to claim 17, wherein the pixel drive circuit further comprises a first initialization transistor, a compensation transistor and an isolation transistor, a first electrode of the first initialization transistor is connected to a first initial signal line, a second electrode of the first initialization transistor and a first electrode of the compensation transistor are connected to a first electrode of the isolation transistor, a second electrode of the isolation transistor is connected to a gate electrode of the drive transistor, and a second electrode of the compensation transistor is connected to a second electrode of the drive transistor; the method further comprises: turning on the isolation transistor at least twice prior to the data writing stage.

19. The method according to claim 17, wherein the method further comprises a node reset stage between the data writing stage and the light emitting stage, and in the node reset stage, a first electrode and the second electrode of the drive transistor are reset.

20. The display substrate according to claim 4, wherein the pixel drive circuit further comprises a first initialization transistor, a compensation transistor and an isolation transistor, a first electrode of the first initialization transistor is connected to a first initial signal line, a second electrode of the first initialization transistor and a first electrode of the compensation transistor are connected to a first electrode of the isolation transistor, a second electrode of the isolation transistor is connected to a gate electrode of the drive transistor, and a second electrode of the compensation transistor is connected to a second electrode of the drive transistor.
